(19) United States
(12) Patent Application Publication
(10) Pub. No.: US 2018/0147808 A1
(43) Pub. Date: May 31, 2018

(54) LAMINATED FILM

(71) Applicant: FUJIFILM Corporation, Tokyo (JP)

(72) Inventors: Satoshi KUNIYASU, Kanagawa (JP); Tamotsu SAIKAWA, Kanagawa (JP)

(73) Assignee: FUJIFILM Corporation, Tokyo (JP)

(21) Appl. No.: 15/878,897

(22) Filed: Jan. 24, 2018

Related U.S. Application Data
(63) Continuation of application No. PCT/JP2016/072170, filed on Jul. 28, 2016.

(30) Foreign Application Priority Data
Jul. 31, 2015 (JP) 2015-152784

(51) Int. Cl. B32B 3/02; B32B 27/30; B32B 27/08; B32B 27/38; B32B 27/20; B29C 41/00; B29C 41/46; C23C 16/34; C23C 16/50; B32B 37/18; B32B 38/00

(52) U.S. Cl. CPC B32B 3/02; B29K 2033/08; B32B 27/08; B32B 27/38; B32B 27/20; B29C 41/003; B29C 41/46; C23C 16/345; C23C 16/50; B32B 37/185; B32B 38/0004; B32B 2457/202; B32B 2255/20; B32B 2255/10; B32B 27/308

(57) ABSTRACT

An object of the present invention is to provide a laminated film including a functional layer such as a quantum dot layer and having an appropriate shape, in which a member such as a quantum dot performing a function can be prevented from deteriorating due to the permeation of oxygen or the like from an end face. The object is achieved by a laminated film including a functional layer laminate having a functional layer and a gas barrier layer laminated on the functional layer and an end face sealing layer covering at least some of end faces of the functional layer laminate, in which the planar shape of the functional layer laminate is a shape in which the corners of a polygon are cut out, or the end faces of the functional layer laminate have a tapered shape.

### CROSS-REFERENCE TO RELATED APPLICATIONS

This application is a Continuation of PCI International Application No. PCT/JP2016/072170 filed on Jul. 28, 2016, which claims priority under 35 U.S.C. § 119(a) to Japanese Patent Application No. 2015-152784 filed on Jul. 31, 2015. The above application is hereby expressly incorporated by reference, in its entirety, into the present application.

### BACKGROUND OF THE INVENTION

### 1. Field of the Invention

The present invention relates to a laminated film used in a backlight or the like of a liquid crystal display.

### 2. Description of the Related Art

As an image display device that consumes less power and occupies a small space, a liquid crystal display (hereinafter, referred to as LCD as well) is increasingly widely used year after year. Furthermore, in recent years, for the liquid crystal display, a further reduction in power consumption, the enhancement of color reproducibility, and the like have been required as the improvement of LCD performance.

As the reduction in power consumption is required for LCD, in order to increase light use efficiency and enhance color reproducibility in a backlight (backlight unit), the use of a quantum dot which emits light by converting the wavelength of incidence rays in the backlight is suggested.

The quantum dot is in an electronic state of which the movement is restricted in all directions in a three-dimensional space. In a case where a semiconductor nanoparticle is three-dimensionally surrounded by a high-potential barrier, the nanoparticle becomes a quantum dot. The quantum dot exhibits various quantum effects. For example, the quantum dot exhibits “quantum size effect” in which the state density (energy level) of an electron becomes discrete. According to the quantum size effect, by changing the size of the quantum dot, the absorption wavelength-emission wavelength of light can be controlled.

Generally, by being dispersed in a matrix formed of a resin such as an acrylic resin or an epoxy resin, quantum dots are made into a quantum dot layer. For example, the quantum dot layer is used as a quantum dot film for wavelength conversion by being disposed between a backlight and a liquid crystal panel.

In a case where excitation light from a backlight is incident on the quantum dot film, the quantum dots are excited and emit fluorescence. At this time, in a case where quantum dots having different emission characteristics are used, light having a narrow half-width such as red light, green light, and blue light are emitted, and hence white light can be realized. Because the fluorescence from the quantum dots has a narrow half-width, by appropriately selecting the wavelength, it is possible to obtain white light with high luminance or to prepare a design so as to obtain excellent color reproducibility.

Incidentally, unfortunately, the quantum dots easily deteriorate due to oxygen or the like, and the emission intensity of the quantum dots deteriorates due to a photo-oxidation reaction. Therefore, in a quantum dot film, by laminating a gas barrier film on both surfaces of a quantum dot layer, the quantum dot layer is protected.

However, in a case where both surfaces of the quantum dot layer are simply sandwiched between gas barrier films, unfortunately, moisture or oxygen permeates the quantum dot layer from the end face not being covered with the gas barrier film, and hence the quantum dots deteriorate.

Accordingly, a method is suggested in which in addition to the both surfaces of a quantum dot layer, the periphery of the quantum dot layer is also sealed with a gas barrier film or the like.

For example, WO2012/102107A describes a composition obtained by dispersing quantum dot phosphors in a cycloolefin (co)polymer at a concentration within a range of 0.0% to 20% by mass, and describes a constitution including a gas barrier layer that coats the entire surface of a resin-molded material in which quantum dots are dispersed. WO2012/102107A also describes that the gas barrier layer is a gas barrier film forming a silica film or an alumina film on at least one surface of the resin layer.

JP2013-544018A describes a display backlight unit including a remote phosphor film containing an emission quantum dot (QD) aggregate, and describes a constitution in which a QD phosphor material is sandwiched between two gas barrier films, and an inert region having gas barrier properties is located in a region sandwiched between the two gas barrier films at the periphery around the QD phosphor material.

JP2009-283441 A describes a light emitting device including a color conversion layer that converts at least a portion of colored light emitted from a light source portion into another colored light and an impermeable sealing sheet that seals the color conversion layer, and describes a constitution including a second adhesive layer provided in the form of a frame along the outer periphery of a phosphor layer that becomes the color conversion layer, that is, surrounding the planar shape of the phosphor layer, in which the second adhesive layer formed of an adhesive material having gas barrier properties.

Furthermore, JP2010-61098A describes a quantum dot wavelength converter having a quantum dot layer (wavelength converting portion) and sealing members formed of silicone or the like that seals the quantum dot layer, and describes a constitution in which the quantum dot layer is sandwiched between the sealing members, and the sealing members are bonded to each other on the periphery of the quantum dot layer.

### SUMMARY OF THE INVENTION

Incidentally, a laminated film containing quantum dots that is used for LCD is a thin film having a thickness of about 50 to 350 μm.

Coating the entire surface of the thin quantum dot layer with a gas barrier film as in WO2012/102107A is extremely difficult, and doing such a thing has a problem of poor productivity. In addition, in a case where the gas barrier film is folded, the barrier layer cracks, and this leads to a problem of the deterioration of gas barrier properties.

JP2013-544018A and JP2009-283441A describe a constitution in which a protective layer having gas barrier properties is formed in an end face region of a quantum dot layer sandwiched between two gas barrier films, which is a so-called dam filling-type laminated film.

The darn filling-type laminated film is prepared by forming a protective layer in the peripheral portion of one gas barrier film, then forming a resin layer in the region surrounded by the protective layer, and then laminating the other gas barrier film on the protective layer and the resin layer. In this manufacturing method, the entire process is performed by a batch method, and hence the method has a problem of extremely poor productivity. Furthermore, because the width of the protective layer increases, the quantum dot layer is not formed on the edge. Accordingly, the area of an effectively usable region decreases, and this leads to a problem of the enlargement of a so-called frame portion.

In the constitution described in JP2010-61098A in which the opening on the edge of two gas barrier films sandwiching the quantum dot layer therebetween is narrowed and sealed, the thickness of the quantum dot layer on the edge decreases. Accordingly, the area of an effectively usable region decreases as described above, and this leads to the problem of the enlargement of a frame portion. In addition, because a barrier layer having high gas barrier properties is generally hard and brittle, in a case where a gas barrier film having such a barrier layer is suddenly curved, unfortunately, the barrier layer cracks, and the gas barrier properties deteriorate.

Therefore, the inventors of the present invention examined, as a constitution in which the permeation of oxygen or moisture from an end face is inhibited, the area of a frame portion is reduced such that an effectively usable region of a quantum dot layer is enlarged, and cracking and the like of a barrier layer is prevented, a constitution in which a sealing layer having gas barrier properties is provided on an end face of a laminated film including a quantum dot layer and a gas harrier film such that the end face is sealed.

However, because the laminated film including quantum dots is extremely thin as described above, it is difficult to properly provide the sealing layer on only the end face of the laminated film. Specifically, a problem in that the sealing layer is unnecessarily enlarged in a film surface direction of the laminated film at the corner of the laminated film and a problem in that the sealing layer is also formed on the main surface (largest surface) of the laminated film may occur. The film surface direction of the laminated film is a direction orthogonal to the lamination direction.

As a result, the formation of the edge sealing layer leads to a problem in that the shape of the laminated film in the film surface direction becomes different from the intended shape, and that the thickness of the laminated film becomes uneven. The thickness of the laminated film is the size of the laminated film in the lamination direction.

The present invention is for solving the aforementioned problems of the related art, and an object thereof is to provide a laminated film which includes a functional layer such as a quantum dot layer and has an appropriate shape or thickness in the film surface direction, in which the members performing optical functions such as quantum dots can be prevented from deteriorating due to the permeation of oxygen or the like from the end face.

In order to achieve the aforementioned object, according to a first aspect of the laminated film of the present invention, there is provided a laminated film comprising a functional layer laminate including a functional layer and a gas barrier layer laminated on at least one main surface of the functional layer and an end face sealing layer covering at least some of end faces of the functional layer laminate, in which a planar shape of the functional layer laminate is a shape in which corners of a polygon are cut out.

In the first aspect of the laminated film of the present invention, it is preferable that the planar shape of the functional layer laminate is preferably a shape in which the corners of a polygon are chamfered at least in the form of a straight line or a curved line.

A length of one side of the chamfered portion is preferably 0.1 to 1 mm, or the chamfered portion is preferably an arc having a radius of 0.1 to 1 mm.

The planar shape of the functional layer laminate is preferably a shape in which the corners of the polygon are cut out in the form of a quadrangle.

A length of one side of the quadrangle is preferably 0.1 to 1 mm.

The planar shape of the functional layer laminate is preferably a shape in which the corners of a rectangle or a square are cut out.

The planar shape of the functional layer laminate is preferably a shape in which all the corners of a polygon are cut out.

According to a second aspect of the laminated film of the present invention, there is provided a laminated film comprising a functional layer laminate including a functional layer and a gas harrier layer laminated on at least one main surface of the functional layer and an end face sealing layer covering at least some of end faces of the functional layer laminate, in which the at least some of the end faces of the functional layer laminate have a tapered shape.

In the first aspect of the laminated film of the present invention, it is preferable that the end faces of the functional layer laminate have a tapered shape inclining to one side.

The end faces of the functional layer laminate preferably have a tapered shape having an apex.

All of the end faces of the functional layer laminate preferably have a tapered shape.

According to the present invention, it is possible to provide a laminated film having an optically functional layer such as a quantum dot layer, in which functional materials such as quantum dots can be prevented from deteriorating due to the permeation of oxygen or the like from end faces of the optically functional layer laminate due to an end face sealing layer sealing the end faces, and the end face sealing layer is prevented from being formed in an unnecessary portion such that the laminated film has an appropriate shape in a film surface direction (direction orthogonal to the lamination direction) and an appropriate thickness (size in the lamination direction).

### BRIEF DESCRIPTION OF′THE DRAWINGS

FIG. 1A is a plan view schematically showing an example of a laminated film of the present invention.

FIG. 1B is a cross-sectional view taken along the line b-b in FIG. 1A.

FIG. 2 is a cross-sectional view schematically showing an example of a gas barrier layer used in the laminated film of the present invention.

FIG. 3A is a schematic view for illustrating a laminated film of the related art.

FIG. 3B is a schematic view for illustrating the laminated film of the related art.

FIG. 3C is a schematic view for illustrating the laminated film of the present invention.

FIG. 4 is a schematic view for illustrating another example of laminated film of the present invention.

FIG. 5 is a schematic view for illustrating another example of the laminated film of the present invention.

FIG. 6A is a cross-sectional view schematically showing another aspect of the laminated film of the present invention.

FIG. 6B is a cross-sectional view schematically showing another aspect of the laminated film of the present invention.

FIG. 7A is a schematic view for illustrating an example of a manufacturing method for manufacturing the laminated film of the present invention.

FIG. 7B is a schematic view for illustrating an example of the manufacturing method for manufacturing the laminated film of the present invention.

FIG. 7C is a schematic view for illustrating an example of the manufacturing method for manufacturing the laminated film of the present invention.

FIG. 8 is a schematic view for illustrating another example of the manufacturing method for manufacturing the laminated film of the present invention.

FIG. 9 is a schematic view for illustrating another example of the manufacturing method for manufacturing the laminated film of the present invention.

### DESCRIPTION OF THE PREFERRED EMBODIMENTS

Hereinafter, the laminated film and the method for manufacturing a laminated film of the present invention will be specifically described based on suitable embodiments shown in the attached drawings.

The following components will be described based on typical embodiments of the present invention in some cases, but the present invention is not limited to the embodiments.

In the present specification, a range of numerical values described using “to” means a range including the numerical values listed before and after “to” as a lower limit and an upper limit respectively.

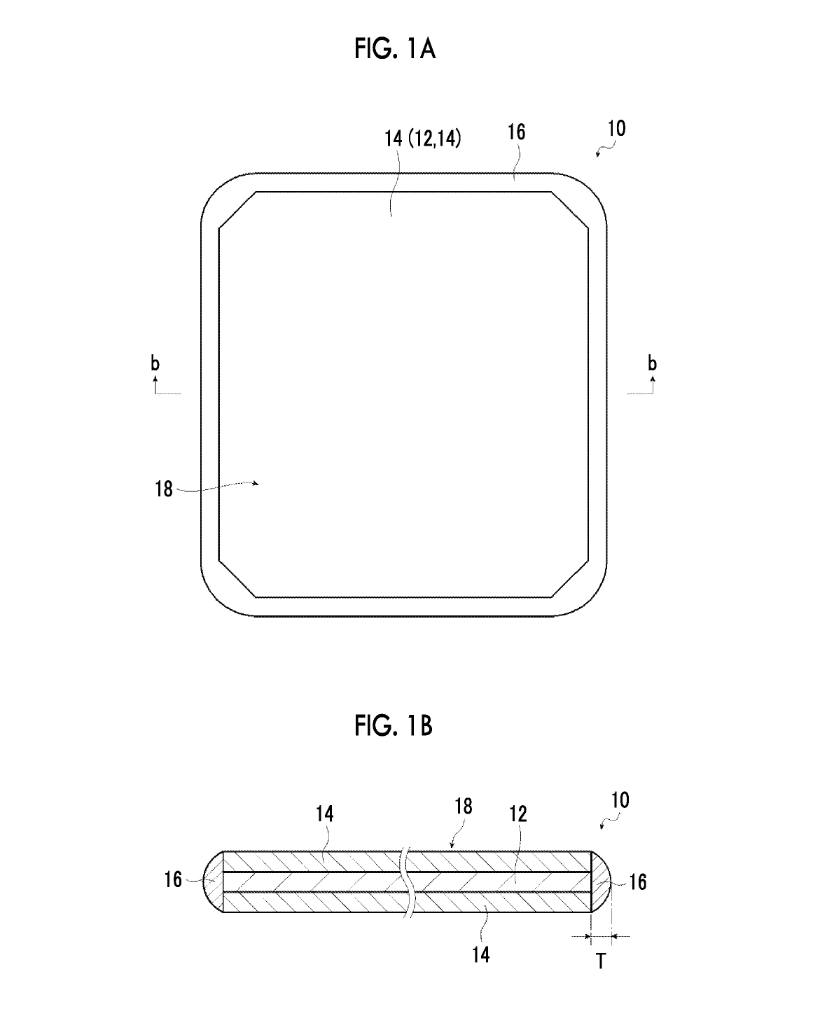

FIG. 1A is a plan view schematically showing an example of the laminated film of the present invention. FIG. 1B is a cross-sectional view taken along the line b-b in FIG. 1A. The plan view is a view obtained in a case where a laminated film 10 of the present invention is seen in a direction orthogonal to the main surface (largest surface) of an optically functional layer 12. The planar shape is a shape seen in a case where the laminated film 10 is observed in the same direction as described above.

Basically, the laminated film 10 shown in FIGS. 1A and 1B has the optically functional layer 12, gas harrier layers 14, and an end face sealing layer 16. As shown in FIG. 1B, the laminated film 10 has a constitution in which the gas barrier layer 14 is laminated on both surfaces (both the main surfaces) of the sheet-like optically functional layer 12, and the entirety of all of the end faces of a functional layer laminate 18 obtained by sandwiching the optically functional layer 12 between the gas barrier layers 14 is covered with the end face sealing layer 16.

In the example illustrated in the drawing, the planar shape of the functional layer laminate 18 obtained by sandwiching the optically functional layer 12 between the gas barrier layers 14 is rectangular, for example. However, the present invention is not limited thereto, and as the planar shape of the functional layer laminate 18, it is possible to use various polygonal shapes such as a square and a hexagon.

The laminated film of the present invention is suitably used as a laminated film such as a quantum dot film used in a display and the like. Therefore, examples of the aforementioned planar shape suitably include the rectangle illustrated in the drawing and a square.

In the example illustrated in the drawing, the functional layer laminate 18 has a layer constitution in which the optically functional layer 12 is sandwiched between the gas barrier layers 14. However, in addition to this, various layer constitutions can be used.

Examples of the layer constitutions include a constitution in which a diffusion layer is laminated on the surface of one of the gas barrier layers 14 in the constitution shown in FIG. 1B, a constitution in which an anti-Newton ring layer is laminated on the surface of one of the gas barrier layers 14 in the constitution shown in FIG. 1B, a constitution in which a diffusion layer is laminated on the surface of one of the gas barrier layers 14 while an anti-Newton ring layer is laminated on the surface of the other gas harrier layer 14 in the constitution shown in FIG. 1B, and the like. Furthermore, a constitution in which an adhesive layer, a protective layer, and the like are laminated may be adopted.

That is, in the laminated film of the present invention, laminates having various layer constitutions can be used as the functional layer laminate 18, as long as the functional layer laminates have a constitution in which a gas barrier layer is laminated on one main surface of an optically functional layer and preferably have a constitution in which a gas barrier layer is laminated on both the main surfaces of an optically functional layer.

In the present invention, the functional layer laminate has a planar shape in which the corners of a polygon are cut out.

This point will be specifically described later.

The optically functional layer 12 is a layer for performing a desired optical function such as wavelength conversion, and a sheet-like material having a quadrangular planar shape, for example.

As the functional layer 12, it is possible to use various layers performing optical functions, such as a wavelength conversion layer like a quantum dot layer, a light extraction layer, an organic electro luminescence layer (organic EL layer), and a photoelectric conversion layer used in a solar cell.

Particularly, by having the end face sealing layer 16, the optically functional layer 12 enables the characteristics of the laminated film of the present invention to be sufficiently exhibited, such as being able to prevent an optically functional material from deteriorating due to oxygen permeating from the end face. Therefore, a quantum dot layer, which is used in a liquid crystal display (LCD) or the like assumed to be used in various environments such as an in-vehicle environment with a high temperature and a high humidity and in which the deterioration of quantum dots resulting from oxygen becomes a big issue, can be suitably used as the optically functional layer 12.

In the laminated film of the present invention, the functional layer is not limited to the optically functional layer 12, and various known functional layers performing a predetermined function can be used.

As described above, as the optically functional layer 12, a quantum dot layer is suitably used. In the following description, the optically functional layer 12 will be referred to as a functional layer 12 as well.

For example, the quantum dot layer is a layer obtained by dispersing a large number of quantum dots in a matrix such as a resin, and is a wavelength conversion layer having a function of converting the wavelength of light incident on the functional layer 12 and emitting the light.

For instance, in a case where blue light emitted from a backlight not shown in the drawing is incident on the functional layer 12, by the effect of the quantum dots contained in the optically functional layer 12, the functional layer 12 performs wavelength conversion such that at least a portion of the blue light becomes red light or green light, and emits the light.

Herein, the blue light refers to light having an emission wavelength centered at a wavelength range of 400 to 500 nm, the green light refers to light having an emission wavelength centered at a wavelength range of a wavelength of longer than 500 nm to a wavelength of equal to or shorter than 600 nm, and the red light refers to light having an emission wavelength centered at a wavelength range of a wavelength of longer than 600 nm to a wavelength of equal to or shorter than 680 nm.

The function of wavelength conversion that the quantum dot layer performs is not limited to the constitution in which the wavelength conversion is performed to change the blue light into the red light or the green light, and at least a portion of incidence rays may be converted into light having a different wavelength.

The quantum dot emits fluorescence by being excited with at least excitation light incident thereon.

The type of the quantum dot contained in the quantum dot layer is not limited, and according to the required wavelength conversion performance or the like, various known quantum dots may be appropriately selected.

Regarding the quantum dot, for example, paragraphs “0060” to “0066” in JP2012-169271A can be referred to, but the present invention is not limited thereto. As the quantum dot, commercially available products can be used without restriction. Generally, the emission wavelength of the quantum dot can be adjusted by the composition or size of the particles.

Although it is preferable that quantum dots are evenly dispersed in a matrix, the quantum dots may be unevenly dispersed in the matrix.

Furthermore, one kind of quantum dot may be used singly, or r more kinds of quantum dots may be used in combination.

In a case where two or more kinds of quantum dots are used in combination, quantum dots that emit light having different wavelengths may be used.

Specifically, known quantum dots include a quantum dot (A) having an emission wavelength centered at a wavelength range of 600 to 680 nm, a quantum dot (B) having an emission wavelength centered at a wavelength range of 500 to 600 nm, and a quantum dot (C) having a emission wavelength centered at a wavelength range of 400 to 500 nm. The quantum dot (A) emits red light by being excited with excitation light, the quantum dot (B) emits green light, and the quantum dot (C) emits blue light. For example, in a case where blue light is caused to incident on a quantum dot-containing laminate containing the quantum dot (A) and the quantum dot (B) as excitation light, by the red light emitted from the quantum dot (A), the green light emitted from the quantum dot (B), and the blue light transmitted through the quantum dot layer, white light can be realized. Furthermore, in a case where ultraviolet light is caused to incident on the quantum dot layer containing the quantum dots (A), (B), and (C) as excitation light, by the red light emitted from the quantum dot (A), the green light emitted from the quantum dot (B), and the blue light emitted from the quantum dot (C), white light can be realized.

As a quantum dot, a so-called quantum rod which has a rod shape and emits polarized light with directionality or a tetrapod-type quantum dot may be used.

The type of the matrix of the quantum dot layer is not limited, and various resins used in known quantum dot layers can be used.

Examples of the matrix include a polyester-based resin (for example, polyethylene terephthalate and polyethylene naphthalate), a (meth)acrylic resin, a polyvinyl chloride-based resin, a polyvinylidene chloride--based resin, and the like. Alternatively, as the matrix, it is possible to use a curable compound having a polymerizable group. The type of the polymerizable group is not limited, but the polymerizable group is preferably a (meth)acrylate group, a vinyl group, or an epoxy group, more preferably a (meth)acrylate group, and particularly preferably an acrylate group. In a polymerizable monomer having two or more polymerizable groups, the polymerizable groups may be the same as or different from each other.

Specifically, for example, a resin containing a first polymerizable compound and a second polymerizable compound described below can be used as a matrix.

The first polymerizable compound is preferably one or more compounds selected from the group consisting of a (meth)acrylate monomer having two or more functional groups and a monomer having two or more functional groups selected from the group consisting of an epoxy group and an oxetanyl group.

Examples of the (meth)acrylate monomer having two or more functional groups preferably include difunctional (meth)acrylate monomers such as neopentyl glycol di(meth)acryl ate, 1,9-nonanediol di(meth)acrylate, tripropylene glycol di(meth)acrylate, ethylene glycol di(meth)acrylate, tetraethylene glycol di(meth)acrylate, hydroxypivalic acid neopentyl glycol di(meth)acrylate, polyethylene glycol di(meth)acrylate, dicyclopentenyl (meth)acrylate, dicyclopentenyloxyethyl (meth)acrylate, and dicyclopentanyl di(meth)acrylate.

Examples of the (meth)acrylate monomer having two or more functional groups preferably include (meth)acrylate monomers having three or more functional groups such as epichlorohydrin (ECH)-modified glycerol tri(meth)acrylate, ethylene oxide (EO)-modified glycerol tri(meth)acrylate, propylene oxide (PO)-modified glycerol tri(meth)acrylate, pentaerythritol triacrylate, pentaerythritol tetraacrylate, EO-modified phosphoric acid triacrylate, trimethylolpropane tri(meth)acrylate, caprolactone-modified trimethylolpropane tri(meth)acrylate, EO-modified trimethylolpropane tri(meth)acrylate, PO-modified trimethylolpropane tri(meth)acrylate, tris(acryloxyethyl)isocyanurate, dipentaerythritol hexa(meth)acrylate, dipentaerythritol penta(meth)acrylate, caprolactone-modified dipentaerythritol hexa(meth)acrylate, dipentaerythritol hydroxypenta(meth)acrylate, alkyl-modified dipentaerythritol penta(meth)acrylate, dipentaerythritol poly(meth)acrylate, alkyl-modified dipentaerythritol tri(meth)acrylate, ditrimethylolpropane tetra(meth)acrylate, pentaerythritol ethoxy tetra(meth)acrylate, and pentaerythritol tetra(meth)acrylate.

As the monomer having two or more functional groups selected from the group consisting of an epoxy group and an oxetanyl group, an aliphatic cyclic epoxy compound, bisphenol A diglycidyl ether, bisphenol F diglycidyl ehter, bisphenol S diglycidyl ether, brominated bisphenol A diglycidyl ether, brominated bisphenol F diglycidyl ether, brominated bisphenol S diglycidyl ether, hydrogenated bisphenol A diglycidyl ether, hydrogenated bisphenol F diglycidyl ether, hydrogenated bisphenol S diglycidyl ether, 1,4-butanediol diglycidyl ether, 1,6-hexanediol diglycidyl ether, glycerin triglycidyl ether, trimethylolpropane triglycidyl ether, polyethylene glycol diglycidyl ether, polypropylene glycol diglycidyl ethers; polyglycidyl ethers of polyether polyol obtained by adding one kind or two or more kinds of alkylene oxide to an aliphatic polyhydric alcohol such as ethylene glycol, propylene glycol, or glycerin; diglycidyl esters of aliphatic long-chain dibasic acid; glycidyl esters of higher fatty acids; a compound containing epoxycycloalkane, and the like are suitably used.

Examples of commercially available products that can be suitably used as the monomer having two or more functional groups selected from the group consisting of an epoxy group and an oxetanyl group include CELLOXIDE 2021P and CELLOXIDE 8000 manufactured by Daicel Corporation, 4-vinylcyclohexene dioxide manufactured by Sigma-Aldrich Co. LLC., and the like. One kind of these monomers can be used singly, or two or more kinds of these monomers can be used in combination.

The monomer having two or functional groups selected from the group consisting of an epoxy group and an oxetanyl group may be prepared by any method. For example, the monomer can be synthesized with reference to the documents such as “Experimental Chemistry Course 20, Organic Synthesis II”, pp. 213˜, 1992, MARUZEN SHUPPAN K.K, “The chemistry of heterocyclic compounds-Small Ring Heterocycles, part 3 Oxiranes”, Ed. By Alfred Hasfner, 1985, John & Wiley and sons, An Interscience Publication, New York, 1985, “Adhesion”, Yoshimura, Vol. 29, No, 12, 32, 1985, “Adhesion”, Yoshimura, Vol. 30, No. 5, 42, 1986, “Adhesion”, Yoshimura, Vol. 30, No. 7, 42, 1986, JP1999-100378A (JP-H11-100378A), JP2906245B, and JP2926262B.

The second polymerizable compound has a functional group which has hydrogen bonding properties in a molecule and a polymerizable group which can cause a polymerization reaction with the first polymerizable compound.

Examples of the functional group having hydrogen bonding properties include a urethane group, a urea group, a hydroxyl group, and the like.

In a case where the first polymerizable compound is a (meth)acrylate monomer having two or more functional groups, the polymerizable group which can cause a polymerization reaction with the first polymerizable compound may be a (meth)acryloyl group, for example. In a case where the first polymerizable compound is a monomer having two or more functional groups selected from the group consisting of an epoxy group and an oxetanyl group, the polymerizable group which can cause a polymerization reaction may be an epoxy group or an oxetanyl group.

Examples of the (meth)acrylate monomer containing a urethane group include monomers and oligomers obtained by reacting diisocyanate such as tolylene diisocyanate (TDI), diphenylmethane diisocyanate (MDI), hexamethylene diisocyanate (HDI), isophorone diisocyanate (IPDI), and hydrogenated MDI (HMDI) with polyol such as poly(propyleneoxide)diol, poly(tetramethyleneoxide)diol, ethoxylated bisphenol A, ethoxylated bisphenol S spiroglycol, caprolactone-modified diol, and carbonate diol and hydroxyacrylate such as 2-hydroxyethyl (meth)acrylate, 2-hydroxypropyl (meth)acrylate, glycidol di(meth)acrylate, and pentaerythritol triacrylate, and polyfunctional urethane monomers described in JP2002-265650A, JP2002-355936A, JP2002-067238A, and the like. Specifically; examples thereof include an adduct of TDI and hydroxyethyl acrylate, an adduct of IPDI and hydroxyethyl acrylate, an adduct of HDI and pentaerythritol triacrylate (PETA), a compound obtained by making an adduct of TDI and PETA and reacting the remaining isocyanate with dodecyloxyhydroxypropyl acrylate, an adduct of 6,6 nylon and TDI, an adduct of pentaerythritol, TDI, and hydroxyethyl acrylate, and the like, but the present invention is not limited to these.

Examples of commercially available products that can be suitably used as the (meth)acrylate monomer containing a urethane group include AH-600, AT-600, UA-306H, UA-306T, UA-306I, UA-510H, UF-8001G, and DAUA-167 manufactured by KYOEISHA CHEMICAL Co., LTD, UA-160TM manufactured by SHIN-NAKAMURA CHEMICAL CO., LTD., UV-4108F and UV-4117F manufactured by OSAKA ORGANIC CHEMICAL INDUSTRY LTD, and the like. One kind of these monomers can be used singly, or two or more kinds of these monomers can be used in combination.

Examples of the (meth)acrylate monomer containing a hydroxyl group include a compound synthesized by causing a reaction between a compound having an epoxy group and (meth)acrylic acid. Typical examples of the monomer are classified into, depending on the compound having an epoxy group, a bisphenol A type, a bisphenol S type, a bisphenol F type, an epoxidized oil type, a phenol novolac type, and Acyclic type. Specific examples of the monomer include (meth)acrylate obtained by reacting an adduct of bisphenol A and epichlorohydrin with (meth)acrylic acid, (meth)acrylate obtained by reacting phenol novolac with epichlorohydrin and then reacting the product with (meth)acrylic acid, (meth)acrylate obtained by reacting an adduct of bisphenol S and epichlorohydrin with (meth)acrylic acid, (meth)acrylate obtained by reacting epoxidized soybean oil with (meth)acrylic acid, and the like. Examples of the (meth)acrylate monomer having a hydroxyl group also include a (meth)acrylate monomer having a carboxyl group or a phosphoric acid group on the terminal, and the like, but the present invention is not limited thereto.

Examples of commercially available products that can be suitably used as the second polymerizable compound containing a hydroxyl group include epoxy ester, M-600A, 40EM, 70PA, 200PA, 80MFA, 3002M, 3002A, 3000MK, and 3000A manufactured by KYOEISHA CHEMICAL Co., LTD, 4-hydroxybutyl acrylate manufactured by Nippon Kasei Chemical Co., Ltd, monofunctional acrylate A-SA and monofunctional methacrylate SA manufactured by SHIN-NAKAMURA CHEMICAL CO., monofunctional acrylate β-carboxyethyl acrylate manufactured by DAICEL-ALLNEX LTD., JPA-514 manufactured by JOHOKU CHEMICAL CO., LTD, and the like. One kind of these can be used singly, or two or more kinds of these can be used in combination.

A mass ratio of first polymerizable compound:second polymerizable compound may be 10:90 to 99:1, and is preferably 10:90 to 90:10. It is preferable that the content of the first polymerizable compound is greater than the content of the second polymerizable compound. Specifically, (content of first polymerizable compound)/(content of second polymerizable compound) is preferably 2 to 10.

In a case where a resin containing the first polymerizable compound and the second polymerizable compound is used as a matrix, it is preferable that the matrix further contains a monofunctional (meth)acrylate monomer. Examples of the monofunctional (meth)acrylate monomer include acrylic acid, methacrylic acid, and derivatives of these, and more specifically include a monomer having one polymerizable unsaturated bond ((meth)acryloyl group) of (meth)acrylic acid in a molecule. Specific examples of the monomer include the following compounds, but the present invention is not limited thereto.

Examples of the monomer include alkyl (meth)acrylate containing an alkyl group having 1 to 30 carbon atoms such as methyl (meth)acrylate, n-butyl (meth)acrylate, isobutyl (meth)acrylate, 2-ethylhexyl (meth)acrylate, isononyl (meth)acrylate, n-octyl (meth)acrylate, lauryl (meth)acrylate, and stearyl (meth)acrylate; aralkyl (meth)acrylate containing an aralkyl group having 7 to 20 carbon atoms, such as benzyl (meth)acrylate; alkoxyalkyl (meth)acrylate containing an alkoxyalkyl group having 2 to 30 carbon atoms, such as butoxyethyl (meth)acrylate; aminoalkyl (meth)acrylate containing a (monoalkyl or dialkyl) aminoalkyl group having 1 to 20 carbon atoms in total, such as N,N-dimethylaminoethyl (meth)acrylate; (meth)acrylate of polyalkylene glycol alkyl ether containing an alkylene chain having 1 to 10 carbon atoms and terminal alkyl ether having 1 to 10 carbon atoms, such as (meth)acrylate of diethylene glycol ethyl ether, (meth)acrylate of triethylene glycol butyl ether, (meth)acrylate of tetraethylene glycol monomethyl ether, (meth)acrylate of hexaethylene glycol monomethyl ether, monomethyl ether (meth)acrylate of octaethylene glycol, monomethyl ether (meth)acrylate of nonaethylene glycol, monomethyl ether (meth)acrylate of dipropylene glycol, monomethyl ether (meth)acrylate of heptapropylene glycol, and monoethyl ether (meth)acrylate of tetraethylene glycol; (meth)acrylate of polyalkylene glycol aryl ether containing an alkylene chain having 1 to 30 carbon atoms and terminal aryl ether having 6 to 20 carbon atoms, such as (meth)acrylate of hexaethylene glycol phenyl ether; (meth)acrylate having an alicyclic structure containing 4 to 30 carbon atoms in total, such as cyclohexyl (meth)acrylate, dicyclopentanyl (meth)acrylate, isobornyl (meth)acrylate, and methylene oxide-added cyclodecatriene (meth)acrylate; fluorinated alkyl (meth)acrylate having 4 to 30 carbon atoms in total such as heptadecafluorodecyl (meth)acrylate; (meth)acrylate having a hydroxyl group such as 2-hydroxyethyl (meth)acrylate, 3-hydroxypropyl (meth)acrylate, 4-hydroxybutyl (meth)acrylate, mono(meth)acrylate of triethylene glycol, tetraethylene glycol mono(meth)acrylate, hexaethylene glycol mono(meth)acrylate, octapropylene glycol mono(meth)acrylate, and mono- or di(meth)acrylate of glycerol; (meth)acrylate having a glycidyl group such as glycidyl (meth)acrylate; polyethylene glycol mono(meth)acrylate having an alkylene chain containing 1 to 30 carbon atoms, such as tetraethylene glycol mono(meth)acrylate, hexaethylene glycol mono(meth)acrylate, and octapropylene glycol mono(meth)acrylate; (meth)acrylamide such as (meth)acrylamide, N,N-dimethyl (meth)acrylamide, N-isopropyl (meth)acrylamide, 2-hydroxyethyl (meth)acrylamide, and acryloylmorpholine; and the like.

The content of the monofunctional (meth)acrylate monomer with respect to the total mass (100 parts by mass) of the first polymerizable compound and the second polymerizable compound is preferably 1 to 300 parts by mass, and more preferably 50 to 150 parts by mass.

Furthermore, it is preferable that the matrix contains a compound having a long-chain alkyl group containing 4 to 30 carbon atoms. Specifically, it is preferable that at least any one of the first polymerizable compound, the second polymerizable compound, or the monofunctional (meth)acrylate monomer has a long-chain alkyl group having 4 to 30 carbon atoms. It is preferable that long-chain alkyl group is a long-chain alkyl group having 12 to 22 carbon atoms, because then the dispersibility of the quantum dots is improved. The further the dispersibility of the quantum dots is improved, the further the amount of light that goes straight to an emission surface from a light conversion layer increases. Accordingly, the improvement of the dispersibility of the quantum dots is effective for improving front luminance and front contrast.

Specifically, as the monofunctional (meth)acrylate monomer having a long-chain alkyl group containing 4 to 30 carbon atoms, butyl (meth)acrylate, octyl (meth)acrylate, lauryl (meth)acrylate, oleyl (meth)acrylate, stearyl (meth)acrylate, behenyl (meth)acrylate, butyl (meth)acrylamide, octyl (meth)acrylamide, lauryl (meth)acrylamide, oleyl (meth)acrylamide, stearyl (meth)acrylamide, behenyl (meth)acrylamide, and the like are preferable. Among these, lauryl (meth)acrylate, oleyl (meth)acrylate, and stearyl (meth)acrylate are particularly preferable.

Furthermore, the resin which becomes a matrix may contain a compound having a fluorine atom such as trifluoroethyl (meth)acrylate, pentafluoroethyl (meth)acrylate, (perfluorobutyl)ethyl (meth)acrylate, perfluorobutyl-hydroxypropyl (meth)acrylate, (perfluorohexyl)ethyl (meth)acrylate, octafluoropentyl (meth)acrylate, perfluorooctyl ethyl meth)acrylate, and tetrafluoropropyl (meth)acrylate. In a case where the resin contains these compounds, the coating properties can be further improved.

The total amount of the resin, which becomes a matrix, in the quantum dot layer is not limited. The total amount of the resin with respect to a total of 100 parts by mass of the quantum dot layer is preferably 90 to 99.9 parts by mass, and more preferably 92 to 99 parts by mass.

The thickness of the quantum dot layer may be appropriately set according to the thickness of the laminated film 10 or the like. According to the examination performed by the inventors of the present invention, in view of handleability and emission characteristics, the thickness of the quantum dot layer is preferably 5 to 200 μm, and more preferably 10 to 150 μm.

The aforementioned thickness means an average thickness which can be determined by measuring thicknesses of ten or more random spots in the quantum dot layer and calculating an arithmetic mean thereof.

The method for forming the quantum dot layer is not particularly limited, and the quantum dot layer may be formed by a known method. For example, the quantum dot layer can be formed by preparing a composition (paint-coating composition) by means of mixing quantum dots, a resin which becomes a matrix, and a solvent together, coating the gas barrier layer 14 with the composition, and curing the composition.

If necessary, a polymerization initiator, a silane coupling agent, and the like may be added to the composition that becomes the quantum dot layer.

In the laminated film 10, on both surfaces of the functional layer 12 such as a quantum dot layer, the gas barrier layer 14 is laminated such that the entirety of the main surfaces of the functional layer 12 is covered. That is, the laminated film 10 has a constitution in which the functional layer 12 is sandwiched between the gas barrier layers 14.

Herein, as a preferable aspect, the laminated film 10 shown in the drawing includes the gas barrier layer 14 provided on both surfaces of the functional layer 12, but the present invention is not limited thereto. That is, the gas barrier layer 14 may be provided on only one surface of the functional layer 12. However, it is preferable that the gas barrier layer 14 is provided on both surfaces of the functional layer 12, because then the deterioration of the functional layer 12 resulting from oxygen or the like can be more suitably prevented.

In a case where the gas barrier layer 14 is provided on both surfaces of the functional layer 12, the gas barrier layers 14 may be the same as or different from each other.

The gas barrier layer 14 is a layer for inhibiting the permeation of oxygen or the like from the main surface of the functional layer 12 such as a quantum dot layer. Accordingly, it is preferable that the gas barrier layer 14 has high gas barrier properties. Specifically, an oxygen permeability of the gas barrier layer 14 is preferably equal to or lower than 0.1 cc/(m²·day·atm), more preferably equal to or lower than 0.01 cc/(m²·day·atm), and particularly preferably equal to or lower than 0.001 cc/(m²·day·atm).

In a case where the oxygen permeability of the gas barrier layer 14 is equal to or lower than 0.1 cc/(m²·day·atm), it is possible to inhibit the functional layer 12 from deteriorating due to oxygen or the like permeating from the main surface of the functional layer 12 and to obtain a laminated film such as a quantum dot film having long service life.

In the present invention, the oxygen permeability of the gas barrier layer 14, the end face sealing layer 16, or the like may be measured based on known methods or the examples which will be described later.

Furthermore, the unit cc/(m²·day·atm) of oxygen permeability is expressed as 9.87 mL/(m²·day·MPa) in terms of the SI unit.

As the gas barrier layer 14, various materials such as a layer (film) formed of a known material exhibiting gas barrier properties and a known gas barrier film can be used, as long as the materials have sufficient optical characteristics in view of transparency or the like and yield intended gas barrier properties (oxygen barrier properties)

As preferable gas barrier layer 14, a gas barrier film can be exemplified which has an organic and inorganic laminated structure obtained by alternately laminating an organic layer and an inorganic layer on a support. The organic and inorganic laminated structure may be formed on only one surface of a support or both surfaces of a support.

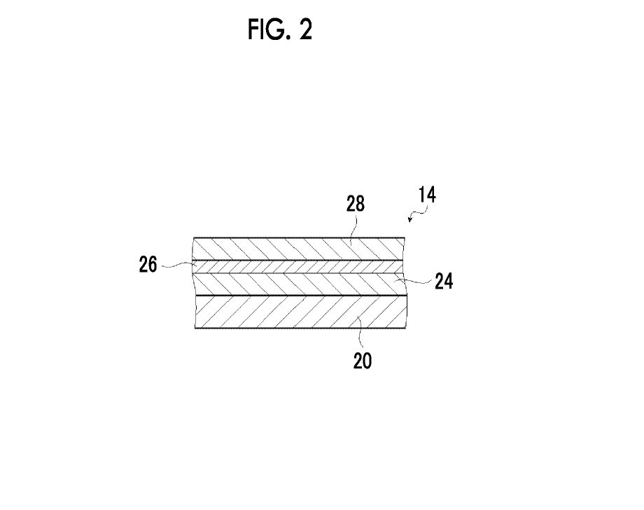

FIG. 2 schematically shows a cross-section of an example of the gas barrier layer 14.

The gas barrier layer 14 shown in FIG. 2 has an organic layer 24 on a support 20, an inorganic layer 26 on the organic layer 24, and an organic layer 28 on the inorganic layer 26.

In the gas harrier layer 14 (gas barrier film), gas barrier properties are mainly exhibited by the inorganic layer 26. The organic layer 24 as an underlayer of the inorganic layer 26 is an underlayer for appropriately forming the inorganic layer 26. The organic layer 28 as an uppermost layer functions as a protective layer for the inorganic layer 26.

In the laminated film of the present invention, the gas barrier layer 14 having an organic and inorganic laminated structure is not limited to the constitution shown in FIG. 2.

For example, the gas barrier layer 14 may not have the organic layer 28 as an uppermost layer that functions as a protective layer.

Furthermore, although the gas barrier layer 14 in example shown in FIG. 2 has only one combination of the inorganic layer and the organic layer as a base, the gas barrier layer 14 may have two or more combinations of the inorganic layer and the organic layer as a base. Generally, the larger the number of combinations of the inorganic layer and the organic layer as a base, the higher the gas barrier properties.

In addition, a constitution may be adopted in which an inorganic layer is formed on the support 20, and one or more combinations of an inorganic layer and an organic layer as a base are provided on the aforementioned inorganic layer.

As the support 20 of the gas barrier layer 14, it is possible to use various materials that are used as a support in known gas barrier films.

Among these, films formed of various resin materials (polymer materials) are suitably used, because these films make it easy to obtain a thin or lightweight support and are suitable for making a flexible support.

Specifically, plastic films formed of polyethylene (PE), polyethylene naphthalate (PEN), polyamide (PA), polyethylene terephthalate (PET), polyvinyl chloride (PVC), polyvinyl alcohol (PVA), polyacrylonitrile (PAN), polyimide (PI), transparent polyimide, a polymethyl methacrylate resin (PMMA), polycarbonate (PC), polyacrylate, polymethacrylate, polypropylene (PP), polystyrene (PS), an acrylonitrile⋅butadiene⋅styrene copolymer (ABS), a cycloolefin copolymer (COC), a cycloolefin polymer (COP), and triacetyl cellulose (TAC) can be suitably exemplified.

The thickness of the support 20 may be appropriately set according to the thickness, size, and the like of the laminated film 10. According to the examination performed by the inventors of the present invention, the thickness of the support 20 is preferably about 10 to 100 μm. In a case where the thickness of the support 20 is within the above range, in view of making a lightweight or thin support, preferable results are obtained.

To the surface of the plastic film of which the support 20 is formed, the functions of preventing reflection, controlling phase difference, improving light extraction efficiency, and the like may be imparted.

In the gas barrier layer 14, the organic layer 24 is formed on the surface of the support 20.

The organic layer 24 formed on the surface of the support 20, that is, the organic layer 24 which becomes an underlayer of the inorganic layer 26 is an underlayer of the inorganic layer 26 mainly exhibiting gas barrier properties in the gas barrier layer 14.

In a case where the gas barrier layer 14 has the organic layer 24, the surface asperities of the support 20, foreign substances having adhered to the surface of the support 20, and the like are concealed, and hence a deposition surface for the inorganic layer 26 can be in a state suitable for forming the inorganic layer 26. Accordingly, it is possible to form an appropriate inorganic layer 26 without voids on the entire surface of the substrate, by removing regions, on which an inorganic compound that becomes the inorganic layer 26 is not easily deposited as a film, such as surface asperities or shadows of foreign substances on the support 20. As a result, a gas barrier layer 14 having an oxygen permeability of equal to or lower than 0.1 cc/(m²·day·atm) can be stably formed.

In the gas barrier layer 14, as the material for forming the organic layer 24, various known organic compounds can be used without restriction.

Specifically, thermoplastic resins such as polyester, a (meth)acrylic resin, a methacrylic acid-maleic acid copolymer, polystyrene, a transparent fluorine resin, polyimide, fluorinated polyimide, polyamide, polyamide imide, polyether imide, cellulose acylate, polyurethane, polyether ether ketone, polycarbonate, alicyclic polyolefin, polyarylate, polyether sulfone, polysulfone, fluorene ring-modified polycarbonate, alicyclic ring-modified polycarbonate, fluorene ring-modified polyester, and an acryl compound, polysiloxane, and films of other organic silicon compounds can be suitably exemplified. A plurality of these materials may be used in combination.

Among these, in view of excellent glass transition temperature or hardness, an organic layer 24 is suitable which is constituted with a polymer of a radically curable compound and/or a cationically curable compound having an ether group as a functional group.

Particularly, an acrylic resin or a methacrylic resin, which contains a polymer of a monomer or an oligomer of acrylate and/or methacrylate as a main component, can be suitably exemplified as the organic layer 24, because such a resin has low refractive index, high transparency, excellent optical characteristics, and the like.

Especially, an acrylic resin or a methacrylic resin can be suitably exemplified which contains, as a main component, a polymer of a monomer or an oligomer of acrylate and/or methacrylate having two or more functional groups, particularly, three or more functional groups, such as dipropylene glycol di(meth)acrylate (DPGDA), trimethylolpropane tri(meth)acrylate (TMPTA), or dipentaerythritol hexa(meth)acrylate (DPHA). Furthermore, it is preferable to use a plurality of acrylic resins or methacrylic resins described above.

The thickness of the organic layer 24 may be appropriately set according to the material for forming the organic layer 24 or the support 20. According to the examination performed by the inventors of the present invention, the thickness of the organic layer 24 is preferably 0.5 to 5 μm, and more preferably 1 to 3 μm.

In a case where the thickness of the organic layer 24 is equal to or greater than 0.5 μm, the surface of the organic layer 24, that is, the deposition surface for the inorganic layer 26 can be smoothed by concealing the surface asperities of the support 20 or the foreign substances having adhered to the surface of the support 20. In a case where the thickness of the organic layer 24 is equal to or smaller than 5 μm, it is possible to suitably inhibit the occurrence of problems such as cracking of the organic layer 24 caused in a case where the organic layer 24 is too thick and curling caused by the gas barrier layer 14.

In a case where the gas barrier film has a plurality of organic layers, such as a case where the gas barrier film has a plurality of combinations of an inorganic layer and an organic layer as a base, the organic layers may have the same thickness or different thicknesses.

The organic layer 24 may be formed by a known method such as a coating method or a flash vapor deposition method.

In order to improve the adhesiveness between the organic layer 24 and the inorganic layer 26 that becomes the underlayer of the organic layer 24, it is preferable that the organic layer 24 (composition that becomes the organic layer 24) contains a silane coupling agent.

In a case where the gas barrier film has a plurality of organic layers 24, such as a case where the gas barrier film has a plurality of combinations of an inorganic layer and an organic layer as a base including the organic layer 28 which will be described later, the organic layers may be formed of the same material or different materials. However, in view of productivity and the like, it is preferable that all the organic layers are formed of the same material.

On the organic layer 24, the inorganic layer 26 is formed using the organic layer 24 as a base.

The inorganic layer 26 is a film containing an inorganic compound as a main component and mainly exhibits gas barrier properties in the gas barrier layer 14.

As the inorganic layer 26, various films can be used which exhibit gas barrier properties and are formed of an inorganic compound such as an oxide, a nitride, or an oxynitride.

Specifically, films formed of inorganic compounds including a metal oxide such as aluminum oxide, magnesium oxide, tantalum oxide, zirconium oxide, titanium oxide, an indium tin oxide (ITO); a metal nitride such as aluminum nitride; a metal carbide such as aluminum carbide; an oxide of silicon such as silicon oxide, silicon oxynitride, silicon oxycarbide, and silicon oxynitrocarbide; a nitride of silicon such as silicon nitride and silicon nitrocarbide; a carbide of silicon such as silicon carbide; hydroxides of these; a mixture of two or more kinds of these; and hydrogenous substances of these can be suitably exemplified.

Particularly, films formed of a silicon compound such as an oxide of silicon, a nitride of silicon, and an oxynitride of silicon can be suitably exemplified, because these films have high transparency and can exhibit excellent gas barrier properties. Among these, a film formed of silicon nitride can be particularly suitably exemplified because this film exhibits better gas barrier properties and has high transparency.

The thickness of the inorganic layer 26 may be appropriately determined according to the material for forming the inorganic layer 26, such that intended gas barrier properties can be exhibited. According to the examination performed by the inventors of the present invention, the thickness of the inorganic layer 26 is preferably 10 to 200 nm, more preferably 10 to 100 nm, and particularly preferably 15 to 75 nm.

In a case where the thickness of the inorganic layer 26 is equal to or greater than 10 nm, an inorganic layer 26 stably demonstrating a sufficient gas barrier performance can be formed. Generally, in a case where the inorganic layer 26 is brittle and too thick, the inorganic layer 26 is likely to experience cracking, fissuring, peeling and the like. However, in a case where the thickness of the inorganic layer 26 is equal to or smaller than 200 nm, the occurrence of cracks can be prevented.

In a case where the gas barrier film has a plurality of inorganic layers 26, the inorganic layers 26 may have the same thickness or different thicknesses.

The inorganic layer 26 may be formed by a known method according to the material forming the inorganic layer 26. Specifically, plasma CVD such as capacitively coupled plasma (CCP)-chemical vapor deposition (CVD) or inductively coupled plasma (ICP)-CVD, sputtering such as magnetron sputtering or reactive sputtering, and a vapor-phase deposition method such as vacuum vapor deposition can be suitably exemplified.

In a case where the gas barrier film has a plurality of inorganic layers, the inorganic layers may be formed of the same material or different materials. However, in view of productivity and the like, it is preferable that all the inorganic layers are formed of the same material.

The organic layer 28 is provided on the inorganic layer 26.

As described above, the organic layer 28 is a layer functioning as a protective layer for the inorganic layer 26. In a case where the laminated film has the organic layer 28 as an uppermost layer, the damage of the inorganic layer 26 exhibiting gas barrier properties can be prevented, and hence the gas barrier layer 14 can stably exhibit intended gas barrier properties. Furthermore, in a case where the laminated film has the organic layer 28, it is also possible to improve the adhesiveness between the functional layer 12, which is obtained by dispersing quantum dots and the like in a resin that becomes a matrix, and the gas barrier layer 14.

The organic layer 28 is basically the same as the aforementioned organic layer 24. In addition to this, as the organic layer 28, it is possible to suitably use an organic layer formed of a graft copolymer which contains an acryl polymer as a main chain and at least either an acryloyl group-terminated urethane polymer or an acryloyl group-terminated urethane oligomer as a side chain and has a molecular weight of 10,000 to 300,000 and has an acryl equivalent of equal to or greater than 500 g/mol.

The thickness of the gas barrier layer 14 may be appropriately set according to the thickness of the laminated film 10, the size of the laminated film 10, and the like.

According to the examination performed by the inventors of the present invention, the thickness of the gas barrier layer 14 is preferably 5 to 100 μm, more preferably 10 to 70 μm, and particularly preferably 15 to 55 μm.

In a case where the thickness of the gas barrier layer 14 is equal to or smaller than 100 μm, it is possible to prevent the gas barrier layer 14, that is, the laminated film 10 from becoming unnecessarily thick. Furthermore, it is preferable that the thickness of the gas barrier layer 14 is equal to or greater than 5 μm, because then the thickness of the functional layer 12 can be made uniform at the time of forming the functional layer 12 between two gas barrier layers 14.

As described above, the laminated film 10 has a constitution in which the gas barrier layer 14 is laminated on both surfaces of the functional layer 12, and the entirety of the end faces of the functional layer laminate 18 including the functional layer 12 and the gas barrier layers 14 is sealed with the end face sealing layer 16.

In a preferable aspect, the laminated film 10 illustrated in the drawing has a constitution in which the entirety of the end faces of the functional layer laminate 18 including the functional layer 12 and the gas barrier layers 14 is sealed with the end face sealing layer 16. However, the present invention is not limited thereto.

That is, for the laminated film of the present invention, for example, in a case where the planar shape of the laminated film 10 is quadrangular, an end face sealing layer covering the entirety of only two end faces facing each other may be provided, or an end face sealing layer covering the entirety of three end faces except for one end face may be provided. Furthermore, an end face sealing layer partially covering each of the end faces of the functional layer laminate 18 may be provided. The type of the end face sealing layer may be appropriately set according to the constitution of a backlight unit in which the laminated film is used, the constitution of the laminated film-mounting portion, and the like.

However, the end face sealing layer 16 preferably covers the end faces of the functional layer laminate 18 in as large area as possible and particularly preferably covers the entirety of the end faces of the functional layer laminate 18, because then the deterioration of the functional layer 12 such as the deterioration of quantum dots caused by the oxygen or the like permeating from the end faces of the functional layer laminate 18 can be more suitably prevented.

The end face sealing layer 16 is formed of a material having gas barrier properties. Preferable examples of the material include a resin layer having an oxygen permeability of equal to or lower than 10 cc/(m²·day·atm). Because the laminated film 10 of the present invention has such an end face sealing layer 16, the member such as a quantum dot performing an optical function is prevented from deteriorating due to oxygen or the like that permeates the optically functional layer 12 from the end face not covered with the gas barrier layer 14.

In a case where the oxygen permeability of the end face sealing layer 16 in the laminated film 10 of the present invention is equal to or lower than 10 cc/(m²·day·atm), oxygen or the like permeating the functional layer 12 from the end faces of the laminate can be sufficiently prevented, and hence the service life of the functional layer 12 can be increased.

Considering the above point, it is preferable that the oxygen permeability of the end face sealing layer 16 is low. Specifically, the oxygen permeability of the end face sealing layer 16 is preferably equal to or lower than 5 cc/(m²·day·atm), and more preferably equal to or lower than 1 cc/(m²·day·atm).

The lower limit of the oxygen permeability of the end face sealing layer 16 is not limited. However, basically, it is preferable that the lower limit of the oxygen permeability is low.

From the viewpoint of gas barrier properties, it is preferable that a thickness T of the end face sealing layer 16 is large. Accordingly, the thickness T of the end face sealing layer 16 may be appropriately set according to the material forming the end face sealing layer 16 and the like, such that the oxygen permeability becomes equal to or lower than 10 cc/(m²·day·atm). The thickness T of the end face sealing layer 16 is in other words the size of the end face sealing layer 16 in a direction orthogonal to the end face of the functional layer laminate 18. As shown in FIG. 1B, in a case where the thickness of the end face sealing layer 16 varies in the thickness direction of the functional layer laminate 18, the thickness at a position where the end face sealing layer 16 becomes thickest is taken as the thickness T of the end face sealing layer 16.

According to the examination performed by the inventors of the present invention, the thickness of the end face sealing layer 16 is preferably equal to or greater than 1 μm. In view of coating properties, it is preferable that the thickness T of the end face sealing layer 16 is equal to or greater than 1 μm, because then the end face sealing layer 16, which can appropriately cover the end faces of the functional layer laminate 18 and has an oxygen permeability of equal to or lower than 10 cc/(m²·day·atm), can be stably formed.

Furthermore, the thickness T of the end face sealing layer 16 is preferably equal to or smaller than 200 μm. It is preferable that the thickness T of the end face sealing layer 16 is equal to or smaller than 200 μm, because then the effective area can be increased with respect to the total area of the laminated film 10, and the adhesiveness between the functional layer laminate 18 and the end face sealing layer 16 can be improved.

From the viewpoints described above, the thickness T of the end face sealing layer 16 is preferably 1 to 200 μm, and more preferably 10 to 100 μm.

In the example shown in FIG. 1, in a cross-section perpendicular to the extension direction of the end face of the functional layer laminate 18, the shape of the end face sealing layer 16 is approximately semicircular.

However, the present invention is not limited thereto, and the shape of the end face sealing layer 16 may be a shape formed of a portion of a circle. Furthermore, various shapes such as a semielliptical shape, a semi-rounded rectangular shape (semiovale shape), and a rectangular shape can also be used.

The end face sealing layer 16, that is, the functional layer laminate 18 can be formed of various known resin materials which make it possible to form the end face sealing layer 16 having necessary gas harrier properties and preferably having an oxygen permeability of equal to or lower than 10 cc/(m²·day·atm).

Generally, the end face sealing layer 16 formed of a resin layer is formed by preparing a composition, which contains a compound (a monomer, a dimer, a timer, an oligomer, a polymer, or the like) that is mainly formed into the end face sealing layer 16, that is, a resin layer, additives that are added if necessary such as a cross-linking agent and a surfactant, an organic solvent, and the like, coating the surface for forming the end face sealing layer 16 with the composition, drying the composition, and, if necessary, polymerizing (cross-linking-curing) the compound mainly constituting the resin layer by ultraviolet irradiation, heating, or the like.

It is preferable that the composition for forming the end face sealing layer 16 in the laminated film 10 of the present invention contains a polymerizable compound or additionally contains a hydrogen bonding compound. The polymerizable compound is a compound having polymerization properties, and the hydrogen bonding compound is a compound having hydrogen bonding properties.

Basically, it is preferable that the end face sealing layer 16 is mainly formed of a polymerizable compound or a hydrogen bonding compound which may be additionally used. A logP value of a degree of hydrophilicity of the polymerizable compound and the hydrogen bonding compound contained in the composition for forming the end face sealing layer 16 is preferably equal to or smaller than 4, and more preferably equal to or smaller than 3.

In the present invention, the LogP value of a degree of hydrophilicity is a logarithm of a partition coefficient of 1-octanol/water. The. LogP value can be calculated by a fragment method, an atomic approach method, and the like. The LogP value described in the present specification is a LogP value calculated from the structure of a compound by using ChemBioDraw Ultra 12.0 manufactured by CambridgeSoft Corporation.

As described above, generally, the functional layer 12 is obtained by dispersing a material performing an optical function in a resin that becomes a matrix.

In many cases, a hydrophobic resin is used as a matrix for the functional layer 12. Particularly, in a case where the functional layer 12 is a quantum dot layer, a hydrophobic resin is frequently used as a matrix.

Basically, in the laminated film 10 in which a resin layer is used as the end face sealing layer 16, the adhesion between the functional layer 12, which is obtained by dispersing quantum dots and the like in a resin that becomes a matrix, and the end face sealing layer 16 is strong. In order to further strengthen the adhesion between the end face sealing layer 16 and the functional layer 12 in which a hydrophobic matrix is used, it is preferable that the end face sealing layer 16 is formed of a hydrophobic compound.

As it is also known, the smaller the logP value of a degree of hydrophilicity of a compound, the higher the hydrophilicity of the compound. That is, in order to form an end face sealing layer 16 having strong adhesion with respect to the functional layer 12, it is preferable that the polymerizable compound or the hydrogen bonding compound as a main component of the end face sealing layer 16 has a large logP value of a degree of hydrophilicity.

In contrast, a resin formed of a compound having high hydrophobicity has a high oxygen permeability. Therefore, in view of the oxygen permeability of the resin layer, it is preferable that the polymerizable compound or the hydrogen bonding compound as a main component of the resin layer has a small logP value of a degree of hydrophilicity

Accordingly, in a case where the end face sealing layer 16 is formed using a polymerizable compound and a hydrogen bonding compound having a logP value of a degree of hydrophilicity of equal to or smaller than 4, it is possible to form en end face sealing layer 16 having a sufficiently low oxygen permeability with securing strong adhesion with respect to the functional layer 12 by appropriate hydrophobicity.

In view of the oxygen permeability, it is preferable that the polymerizable compound and the hydrogen bonding compound have a small logP value of a degree of hydrophilicity. However, in a case where the logP value of a degree of hydrophilicity is too small, the hydrophilicity may be too high, the adhesion between the end face sealing layer 16 and the functional layer 12 may be weakened, and the durability of the end face sealing layer 16 may deteriorate.

Considering the above points, the logP value of a degree of hydrophilicity of the polymerizable compound and the hydrogen bonding compound is preferably equal to or greater than 0.0, and more preferably equal to or greater than 0.5.

The composition forming the end face sealing layer 16 in the laminated film 10 of the present invention contains the hydrogen bonding compound, preferably in an amount of equal to or greater than 30 parts by mass and more preferably in an amount of equal to or greater than 40 parts by mass provided that the total amount of solid contents of the composition is 100 parts by mass.

The total amount of solid contents of the composition is the total amount of components that should remain in the end face sealing layer 16 to be formed, except for an organic solvent in the composition.

It is preferable that the solid contents in the composition forming the end face sealing layer 16 contain a hydrogen bonding compound in an amount of equal to or greater than 30 parts by mass, because then the oxygen permeability can be reduced by strengthening the intermolecular interaction or the like.

A hydrogen bond refers to a non-covalent bond that is formed between a hydrogen atom, which forms a covalent bond with an atom having electronegativity higher than that of the hydrogen atom in a molecule, and another atom or atomic group in the same molecule or different molecules by attractive interaction.

The functional group having hydrogen bonding properties is a functional group containing a hydrogen atom which can form such a hydrogen bond. Specific examples of the functional group include a urethane group, a urea group, a hydroxyl group, a carboxyl group, an amide group, a cyano group, and the like.

Specific examples of compounds having these functional groups include monomers and oligomers which are obtained by reacting diisocyanate such as tolylene diisocyanate (TDI), diphenylmethane diisocyanate (MDI), hexamethylene diisocyanate isophorone diisocyanate (IPDI), and hydrogenated MDI (HMDI) with polyol such as poly(propyleneoxide)diol, poly(tetramethyleneoxide)diol, ethoxylated bisphenol A, ethoxylated bisphenol S spiroglycol, caprolactone-modified dial, and carbonate dial and hydroxyacrylate such as 2-hydroxyethyl (meth)acrylate, 2-hydroxypropyl (meth)acrylate, glycidyl di(meth)acrylate, and pentaerythritol triacrylate.

Examples of the aforementioned compounds also include an epoxy compound obtained by reacting a compound having an epoxy group with a compound such as a bisphenol A-type compound, a bisphenol S-type compound, a bisphenol F-type compound, an epoxidized oil-type compound, and a phenol novolac-type compound and an epoxy compound obtained by reacting alicyclic epoxy with an amine compound, an acid anhydride, and the like.

Examples of the aforementioned compounds also include a cationically polymerized substance of the aforementioned epoxy compound, polyvinyl alcohol (PVA), an ethylene-vinyl alcohol copolymer (EVOH), a butenediol-vinyl alcohol copolymer, polyacrylonitrile, and the like.

Among these, a compound having an epoxy group and a compound obtained by reacting a compound having an epoxy group are preferable, because these compounds less experience cure shrinkage and have excellent adhesiveness with respect to the laminated film.

The composition forming the end face sealing layer 16 in the laminated film 10 of the present invention contains a polymerizable compound having at least one polymerizable functional group selected from a (meth)acryloyl group, a vinyl group, a glycidyl group, an oxetane group, and an alicyclic epoxy group, preferably in an amount of equal to or greater than 5 parts by mass provided that the total amount of solid contents of the composition is 100 parts by mass. The composition contains the polymerizable compound having the aforementioned polymerizable functional group more preferably in an amount of equal to or greater than 10 parts by mass.

In a case where the composition forming the end face sealing layer 16 in the laminated film 10 of the present invention contains the polymerizable compound having at least one polymerizable functional group selected from a (meth)acrylate and the like in an amount of equal to or greater than 5 parts by mass, an end face sealing layer 16 having excellent durability at a high temperature and a high humidity can be realized.

Specific examples of the polymerizable compound having a (meth)acryloyl group include neopentyl glycol di(meth)acrylate, 1,9-nonanediol di(meth)acrylate, tripropylene glycol di(meth)acrylate, ethylene glycol di(meth)acrylate, dicyclopentenyl (meth)acrylate, dicyclopentenyloxyethyl (meth)acrylate, dicyclopentanyl di(meth)acrylate, and the like.

Specific examples of the polymerizable compound having a glycidyl group, an oxetane group, an alicyclic epoxy group, or the like include bisphenol A diglycidyl ether, bisphenol F diglycidyl ether, hydrogenated bisphenol A diglycidyl ether, hydrogenated bisphenol F diglycidyl ether, 1,4-butanediol diglycidyl ether, 1,6-hexanediol diglycidyl ether, glycerin triglycidyl ether, trimethylolpropane triglycidyl ether, and the like.

In the present invention, as the polymerizable compound having a (meth)acryloyl group or a glycidyl group, commercially available products can be suitably used.

As the commercially available products including the polymerizable compound, MAXIVE manufactured by MITSUBISHI GAS CHEMICAL COMPANY, INC, NANOPOX 450, NANOPOX 500, and NANOPOX 630 manufactured by Evonik Industries, a series compounds such as COMPOCERAN 102 manufactured by Arakawa Chemical Industries, Ltd, FLEP and THIOKOL LP manufactured by Toray Fine Chemicals Co., Ltd, a series of compounds such as LOCTITE E-30CL manufactured by Henkel Japan Ltd, a series of compounds such as EPO-TEX353ND manufactured by Epoxy Technology Inc, and the like can be suitably exemplified.

If necessary, the composition forming the end face sealing layer 16 in the laminated film of the present invention may contain a polymerizable compound which does not contain a (meth)acryloyl group, a vinyl group, a glycidyl group, an oxetane group, and an alicyclic epoxy group.

Here, provided that the total amount of solid contents of the composition forming the end face sealing layer 16 is 100 parts by mass, the amount of the polymerizable compound, which does not contain the above functional groups, contained in the composition is preferably equal to or smaller than 3 parts by mass.

In the laminated film 10 of the present invention, particles of an inorganic substance (particles formed of an inorganic compound) may be dispersed in the end face sealing layer 16.

In a case where the end face sealing layer 16 contains the particles of an inorganic substance, the oxygen permeability of the end face sealing layer 16 can be further reduced, and the deterioration of the functional layer 12 resulting from oxygen or the like permeating from the end face can be more suitably prevented.

The size of the particles of an inorganic substance dispersed in the end face sealing layer 16 is not limited, and may be appropriately set according to the thickness of the end face sealing layer 16 or the like. The size (maximum length) of the particles of an inorganic substance dispersed in the end face sealing layer 16 is preferably less than the thickness of the end face sealing layer 16. Particularly, the smaller the size of the particles, the more advantageous.

The size of the particles of an inorganic substance dispersed in the end face sealing layer 16 may be uniform or non-uniform.

The content of the particles of an inorganic substance in the end face sealing layer 16 may be appropriately set according to the size of the particles of an inorganic substance or the like.

According to the examination performed by the inventors of the present invention, the content of the particles of an inorganic substance in the end face sealing layer 16 is preferably equal to or smaller than 50% by mass, and more preferably 10% to 30% by mass. That is, provided that the total amount of solid contents in the composition forming the end face sealing layer 16 is 100 parts by mass, the content of the particles of an inorganic substance is preferably equal to or smaller than 50 parts by mass, and more preferably 10 to 30 parts by mass.

The greater the content of the particles of an inorganic substance is, the more the oxygen permeability of the end face sealing layer 16 is effectively reduced by the particles of an inorganic substance. In a case where the content of the particles of an inorganic substance is equal to or greater than 10% by mass, the effect obtained by the addition of the particles of an inorganic substance becomes more suitable, and an end face sealing layer 16 having a low oxygen permeability can be formed.

It is preferable that the content of the particles of an inorganic substance in the end face sealing layer 16 is equal to or smaller than 50% by mass, because then the adhesiveness or the durability of the end face sealing layer 16 can become sufficient, and the occurrence of cracking at the time of cutting or punching the laminated film can be inhibited.

Specific examples of the particles of an inorganic substance dispersed in the end face sealing layer 16 include inorganic layer-like minerals, silica particles, alumina particles, titania particles, silver particles, copper particles, and the like.

As described above, in the laminated film 10 of the present invention, the end faces of the functional layer laminate 18 obtained by sandwiching the functional layer 12 between gas barrier layers 14 are sealed with the end face sealing layer 16.

In the laminated film of the present invention, the functional layer laminate has a shape in which the corners of a polygon are cut out. In the laminated film 10 illustrated in the drawing, as shown in FIG. 1A which is a plan view, the functional layer laminate 18 has a shape obtained by chamfering by which four corners of the functional layer laminate 18 having a rectangular planar shape (that is, a thin rectangular shape) are cut out in the form of a straight line.

Because the laminated film of the present invention has the aforementioned constitution, an unnecessarily large end face sealing layer 16 is prevented from being formed at the corners of the functional layer laminate 18.

As described above, regarding a laminated film formed by sandwiching an optically functional layer such as a quantum dot layer between gas barrier layers, the inventors of the present invention examined, as a constitution in which the permeation of oxygen or moisture from an end face is prevented from permeating an optically functional layer and the area of an effectively usable region of the quantum dot layer can be enlarged by reducing a frame portion, a constitution in which the end face sealing layer 16 having gas barrier properties is provided on the end faces of the functional layer laminate such that the end face are sealed.

Furthermore, as described above, the end face sealing layer 16 is formed by preparing a composition (paint-coating composition) containing a compound that becomes the end face sealing layer 16 (resin layer), coating the end faces of the functional layer laminate with the composition, and drying the composition or, if necessary, curing the composition with actinic rays.

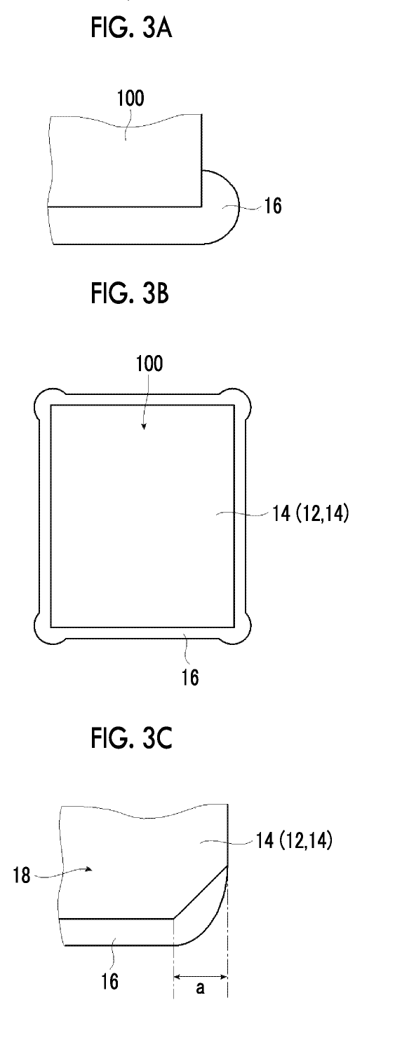

However, because the functional layer laminate is thin, it is difficult to coat only the end faces with the composition. Specifically, as being schematically shown in FIG. 3A, the composition, with which an end face of the functional layer laminate is coated, wraps the adjacent end face at the corner of a functional layer laminate 100 due to the surface tension, capillary action, and the like.

As described above, the end face sealing layer 16 is formed on the all of the four end faces of the rectangular functional layer laminate 100. Consequently, in the laminated film of the related art, as being schematically shown in FIG. 3B, an unnecessarily large end face sealing layer 16 is formed at the corners of the functional layer laminate 100.

For example, in a case where the laminated film is used in LCD or the like, the laminated film is loaded on the LCD or the like by being set in a frame. The aforementioned laminated film having the unnecessarily large end face sealing layer 16 at the corners thereof needs to be set in a frame or the like together with the corners. That is, in the laminated film having the unnecessarily large end face sealing layer 16 at the corners thereof, the size of the laminated film unnecessarily increases in the film surface direction (the direction orthogonal to the lamination direction).

In contrast, in the laminated film 10 of the present invention, the functional layer laminate 18 has a planar shape in which the corners are cut out as if the corners are chamfered.

Therefore, as being schematically shown in FIG. 3C, even in a case where one end face is coated with the composition for forming the end face sealing layer 16, it is possible to prevent the composition from wrapping the adjacent end face.

As a result, as being schematically shown in FIG. 1A, the end face sealing layer 16 is prevented (inhibited) from being unnecessarily enlarged at the corners of the laminated film 10, and hence the laminated film 10 having appropriate shape and size in the surface direction can be obtained.

In the laminated film 10 of the present invention, the size of a cut may be appropriately set according to the size, use, and the like of the laminated film 10, within the range of size that does not cause a problem for practical use.

According to the examination conducted by the inventors of the present invention, the size of the cut at the corners of the functional layer laminate 18 is set such that a length a of one side of the cut preferably becomes 0.1 to 1 mm at the end face of the corners. That is, the corners of the functional layer laminate preferably have a chamfered portion formed by chamfering by which the corners are cut out such that the length a of one side of the cut becomes 0.1 to 1 mm.

It is preferable that the size of the cut of the corners of the functional layer laminate 18 is set such that the length a of one side of the cut becomes equal to or greater than 0.1 mm, because then the cutting performed at the corners of the functional layer laminate 18 brings about a suitable effect, and hence the end face sealing layer 16 can be more reliably prevented from wrapping the adjacent end face.

In addition, it is preferable that the size of the cut of the corners of the functional layer laminate 18 is set such that the length a of one side of the cut becomes equal to or smaller than 1 mm, because then the effective area of the laminated film 10 is suitably secured, and hence a laminated film efficient in terms of area can be obtained.

The length a of one side of the cut may be the same for or different between the end faces adjacent to each other.

The functional layer laminate 18 shown in FIG. 1A and the like has a planar shape in which the corners of a rectangle are chamfered in the form of a straight line, but the present invention is not limited thereto.

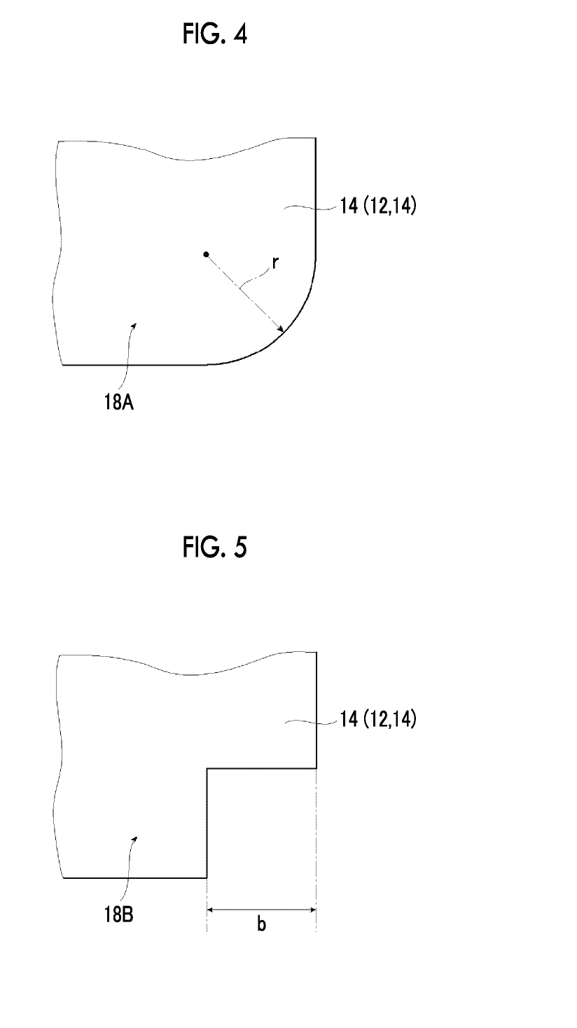

For example, it is also possible to use a functional layer laminate having a planar shape in which the corners of a rectangle are chamfered in the form of a curved line just as a functional layer laminate 18A schematically shown in FIG. 4. That is, it is possible to use a functional layer laminate having a planar shape in which the corners of a rectangle have undergone R processing. In other words, the functional layer laminate may have a planar shape having an arc-like chamfered portion that is obtained by chamfering by which the corners of the functional layer laminate are cut out in the form of a curved line.

The shape of the curved line formed by chamfering may be appropriately determined according to the size, use, and the like of the laminated film. According to the examination conducted by the inventors of the present invention, an arc shape is preferable, and an arc shape having a central angle of 90° illustrated in the drawing is more preferable, because such an arc shape makes it possible to suitably prevent the end face sealing layer 16 from wrapping the adjacent end face, does not cause stress concentration since the arc shape does not have a corner, and thus makes it difficult for the laminated film from cracking or breaking.

A radius r of the aforementioned arc may be appropriately determined according to the size, use, and the like of the laminated film. However, for the same reasons as described above, the radius r is preferably 0.1 to 1 mm.

In the laminated film of the present invention, as the planar shape of the functional layer laminate, in addition to the shape in which the corners of a rectangle are chamfered, various shapes in which the corners of a rectangle (polygon) are cut out can be used.

For example, just as a functional layer laminate 18B schematically shown in FIG. 5, the functional layer laminate may have a planar shape in which the corners of a rectangle are cut out in the form of a quadrangle.

The shape of the quadrangle to be cut out may be appropriately determined according to the size, use, and the like of the laminated film. According to the examination conducted by the inventors of the present invention, it is preferable that the quadrangle is a square or a rectangle, because then the end face sealing layer 16 can be suitably prevented from wrapping the adjacent end face, and the processing becomes easy. That is, a length b of the cut at the corner of the end face may be the same for or different between end faces adjacent to each other, but it is preferable that the length b of the cut is the same for the end faces adjacent to each other.

The length b of the cut at the end face of the corner may be appropriately determined according to the size, use, and the like of the laminated film. However, for the same reasons as described above, the length b is preferably 0.1 to 1 mm.

In the functional layer laminate of the laminated film of the present invention, the shape of the cut at the corner does not need to be the same for all the corners, and the functional layer laminate may have cuts having different shapes.

For example, a single functional layer laminate may have a straight line-like cut shown in FIG. 3C and a curved line-like cut shown in FIG. 4.

In the functional layer laminate, the sizes of cuts at the respective corners may be the same as or different from each other.

In the laminated film of the present invention, it is preferable that the end face sealing layer 16 is formed on the entirety of the end faces of the cuts of the functional layer laminate 18.

The functional layer laminate 18 having a planar shape in which the corners of a rectangle (polygon) are cut out may be prepared by known methods such as cutting, punching processing such as Thompson processing, pinnacle die cutting, milling, and grinding. Cutting may be performed using, for example, scissors, a cutter, a microtome, and a cutting machine.

In the example described above, the functional layer laminate having a planar shape in which the corners of a rectangle (polygon) are cut out is used so as to prevent an unnecessarily large end face sealing layer 16 from being formed at the corners of the laminated film.

In contrast, in a laminated film of a second aspect of the present invention, the end faces of the functional layer laminate are tapered shape such that the end face sealing layer is prevented (inhibited) from being formed on the end faces of the main surface of the functional layer laminate. In other words, in the laminated film of the second aspect of the present invention, the end faces of the functional layer laminate are caused to have a triangular shape such that the end face sealing layer is prevented from being formed on the main surface of the functional layer laminate.

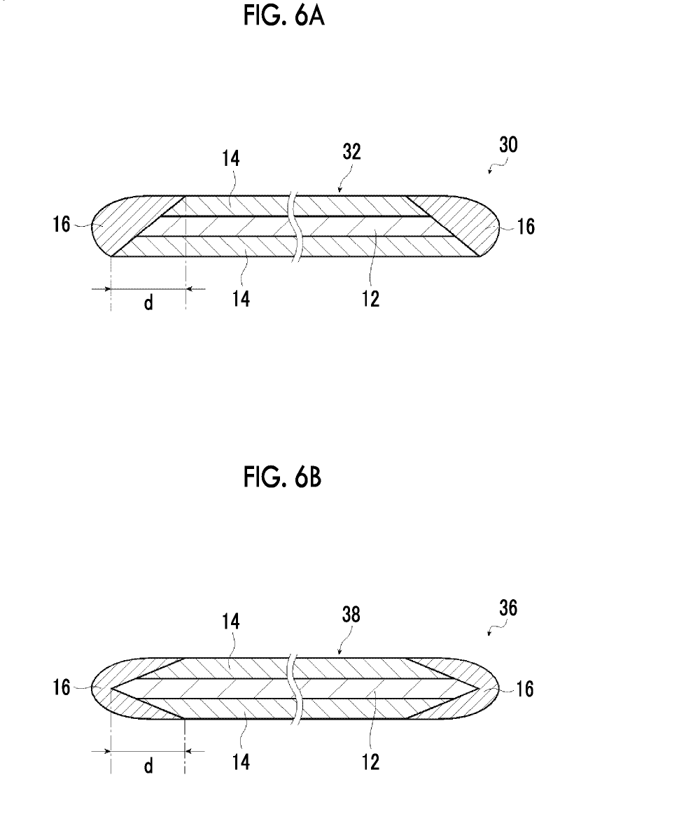

FIG. 6A schematically shows an example of aforementioned functional layer laminate.

The laminated films shown in FIG. 6A and FIG. 6B, which will be described later, have the same constitution as that of the laminated films shown in FIGS. 1A and 1B, and the like described above, except that the functional layer laminates having different end face shapes. Accordingly, the same members are marked with the same references, and the different members will be mainly described.

In a laminated film 30 shown in FIG. 6A, each of the end faces of a functional layer laminate 32 obtained by sandwiching the functional layer 12 between the gas barrier layers 14 have a tapered shape inclining to one side. In other words, the end faces of the functional layer laminate 32 have a right triangular shape in which one side adjacent to the right angle coincides with the surface of the functional layer laminate 32.

As a result, it is possible to prevent the end face sealing layer 16 from being formed on the main surface except for the tapered portions.

As described above, regarding a laminated film formed by sandwiching an optically functional layer such as a quantum dot layer between gas barrier layers, the inventors of the present invention examined, as a constitution in which oxygen or moisture is prevented from permeating an optically functional layer from an end face and the area of an effectively usable region of the quantum dot layer can be enlarged by reducing a frame portion, a constitution in which the end face scaling layer having gas barrier properties is provided on the end faces of the functional layer laminate such that the end faces are sealed.

However, because the functional layer laminate containing quantum dots is extremely thin, it is difficult to provide the end face sealing layer only on the end faces of the thin functional layer laminate, and the end face sealing layer may be formed on the main surface side of the functional layer laminate.

In a case where the sealing layer is formed on the main surface side of the functional layer laminate, the flatness of the laminated film deteriorates, and the thickness of the laminated film increases. In a case where the laminated having poor flatness is laminated on other optical films at the time of being incorporated into LCD or the like, the laminated film itself or other optical films are curved, and hence appropriate performance could not be demonstrated. Furthermore, the thickening of the laminated film is unfavorable for making a thin LCD. Herein, the thickness of the laminated film is a size in the lamination direction, that is, a size in a direction orthogonal to the plane direction.

On the contrary, in the present invention, by tapering the end faces of the functional layer laminate 18, the end face sealing layer 16 is prevented from being formed on the main surface except for the tapered portions.

As described above, the end face sealing layer 16 is formed by preparing a composition containing a compound that becomes the end face sealing layer 16 (resin layer), coating the end faces of the functional layer laminate with the composition, and drying the composition or, if necessary, curing the composition with actinic rays.

In a case where the end faces of the functional layer laminate are flat (rectangular), due to the wettability of the functional layer laminate, the surface tension of the composition, and the like, the composition having adhered to the end faces wraps both the main surfaces (the surfaces of the gas barrier layers 14) of the functional layer laminate. Consequently, at the edge of the functional layer laminate, the end face sealing layer 16 is formed on both the main surfaces of the functional layer laminate, and hence the width of the end face sealing layer 16 becomes larger than the thickness of the functional layer laminate. The width of the end face sealing layer 16 is the size of the functional layer laminate in the thickness direction, that is, the size of the functional layer laminate in the lamination direction.

In contrast, in a case where the end faces of the functional layer laminate 32 are tapered as in the laminated film 30 of the present invention, the composition having adhered to the end faces of the functional layer laminate 32 moves to the tip of the taper along the inclined surface of the taper.

As a result, on the main surface of the functional layer laminate 32, the composition is prevented from wrapping both the main surfaces of the functional layer laminate 32 due to the wettability of the functional layer laminate 18, the surface tension of the composition, and the like, and it is possible to prevent (inhibit) the end face sealing layer 16 from being formed on the main surface of the functional layer laminate 32.

In the second aspect of the present invention, the shape of the taper of the end face of the functional layer laminate is not limited to the shape inclining to one side shown in FIG. 6A.

That is, as in the laminated film 36 schematically shown in FIG. 6B, the end face of a functional layer laminate 38 may have a tapered shape having an apex positioned inside the end face. In other words, the end face of the functional layer laminate may have the shape of an isosceles triangle or an equilateral triangle other than a right triangle.

A length d of the taper at the end face of the functional layer laminate may be appropriately set according to the size, use, and the like of the laminated film, within the range of a size that does not cause a problem for practical use. The length d of the taper is in other words a length in a direction orthogonal to the end face of the functional layer laminate.

According to the examination conducted by the inventors of the present invention, the length d of the taper at the end face of the functional layer laminate is preferably 0.1 to 1 mm.

It is preferable that the length d of the taper is equal to or greater than 0.1 mm, because then the effect obtained by tapering the end face of the functional layer laminate becomes suitable, and the end face sealing layer 16 can be more reliably prevented from wrapping the main surface.

Furthermore, it is preferable that the length d of the taper is equal to or smaller than 1 mm, because then the effective area of the laminated film 10 is suitably secured, and hence a laminated film efficient in terms of area can be obtained.

In the laminated film having the functional layer laminate with tapered end faces, the thickness of the end face sealing layer may be based on the thickness T shown in FIG. 1B described above.

In the laminated film having the functional layer laminate with the tapered end faces, the thickness of the end face sealing layer is a maximum length in the direction of the length d of the taper.

The functional layer laminate having the tapered end faces may be prepared by known methods.

Examples of the methods include a method of polishing the end faces of the functional layer laminate, a method of controlling a blade edge angle of a knife used for manufacturing a functional layer laminate having a predetermined shape, a method in which a knife used for manufacturing a functional layer laminate having a predetermined shape is obliquely brought into contact with the end faces of the functional layer laminate, and the like.

Hereinafter, an example of a method for manufacturing the laminated film of the present invention will be described. The method will be described based mainly on the laminated film 10 shown in FIGS. 1A and 1B, but the laminated films of other aspects can also be manufactured based on the method.

First, the functional layer laminate 18 is prepared.

As the method for preparing the functional layer laminate 18, as described above, the organic layer 24 is formed on the surface of the support 20 by a coating method or the like, and the inorganic layer 26 is formed on the surface of the organic layer 24 by plasma CVD or the like. Then, the organic layer 28 is formed on the surface of the inorganic layer 26 by a coating method or the like, thereby preparing the gas barrier layer 14 (gas harrier film).

It is preferable that the formation of the organic layer and the inorganic layer is performed by a so-called roll-to-roll method. In the following description, “roll-to-roll” will be referred to as “RtoR” as well.

Meanwhile, a composition is prepared which contains an organic solvent, a compound forming a resin to be a matrix, quantum dots and the like and becomes the functional layer 12 such as a quantum dot layer.

Two sheets of gas harrier layers 14 are prepared, and the surface of the organic layer 28 of one of the gas barrier layers 14 is coated with the composition that becomes the functional layer 12. Furthermore, the other sheet of gas barrier layer 14 is laminated on the composition in a state where the organic layer 28 faces the composition side, and ultraviolet curing or the like is performed, thereby preparing a laminate in which the gas barrier layer 14 is laminated on both surfaces of the functional layer 12.

The laminate is cut by, for example, Thompson processing such that the laminate has a planar shape in which the corners of a rectangle are cut out, thereby preparing the functional layer laminate 18.

Alternatively, after the laminate is processed in a predetermined shape, for example, the end faces thereof are polished, thereby preparing the functional layer laminate 32 shown in FIG. 6A.

Thereafter, the end face sealing layer 16 is formed on the end faces of the functional layer laminate 18.

As described above, the end face sealing layer 16 is formed by preparing a composition containing a compound that becomes the end face sealing layer 16, coating the end faces of the functional layer laminate 18 with the composition, and drying the composition or, if necessary, polymerizing the compound that mainly constitutes a resin layer by ultraviolet irradiation, heating, and the like.

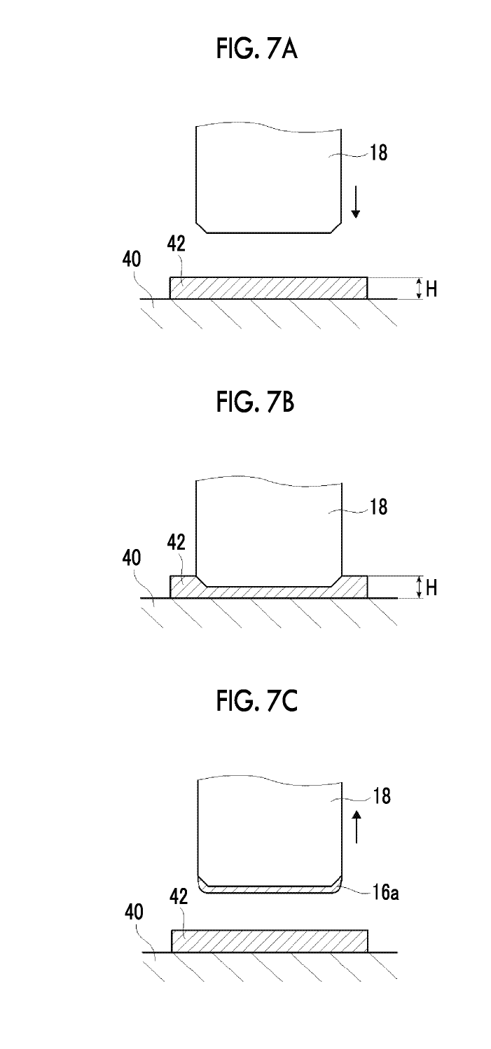

For coating the end faces of the functional layer laminate 18 with the composition, it is possible to use known methods such as ink jet method, spray coating, and dipping (immersion coating). Examples of preferable coating methods include the method of transferring a liquid film as shown in FIGS. 7A to 7C.

In this coating method, first, as shown in FIG. 7A, a liquid film 42 of the composition that becomes the end face sealing layer 16 is formed on a flat plate 40 (for example, a glass plate or a tray). A thickness H of the liquid film 42 may be appropriately set according to the intended thickness of the end face sealing layer 16, the concentration of solid contents in the composition, and the like,

The size of the liquid film 42 in the film surface direction is not limited as long as the entirety of one end face of the functional layer laminate 18 can come into contact with the liquid film 42. For example, the length of one side of the liquid film 42 may be larger than the length of the edge side of the functional layer laminate 18.

Thereafter, as shown in FIG. 7B, the end face of the functional layer laminate 18 is brought into contact with the liquid film 42. Then, as shown in FIG. 7C, the functional layer laminate 18 is lifted up in a vertical direction such that a predetermined amount of a composition 16a that becomes the end face sealing layer 16 adheres to the end face of the functional layer laminate 18.

In the present invention, as described above, the functional layer laminate 18 has a cut at the corners thereof as shown in FIG. 1A and the like. Therefore, the composition 16a can be prevented from spreading from an end face, to which the composition adheres, and wrapping the adjacent end face.

The amount of the end face to be immersed in the liquid film 42 may be appropriately set according to the thickness H of the liquid film 42 and the like.

Alternatively, by tapering the end faces of the functional layer laminate as shown in FIGS. 6A and 6B, it is possible to prevent the composition from adhering to the main surface of the functional layer laminate.

In the aspect shown in FIGS. 6A and 6B in which the end faces of the functional layer laminate are tapered, the amount of the end faces to be immersed in the liquid film 42 is preferably the same as the length d of the taper. Alternatively, it is preferable to immerse the end faces of the functional layer laminate in the liquid film 42, in a state where the tapered surface of each of the end faces of the functional layer laminate is made parallel to the level of the liquid film 42.

It is preferable at the end face sealing layer is formed in the aforementioned manner, because then the end face sealing layer 16 can be reliably formed on the entirety of the end faces of the functional layer laminate and can be suitably prevented from being formed on the main surface of the functional layer laminate.

After the composition is caused to adhere to all the end faces of the functional layer laminate 18 as described above, the composition having adhered to the end feces of the functional layer laminate 18 is dried and, if necessary, cured by ultraviolet irradiation, heating, and the like, thereby forming the end face sealing layer 16.

By forming the end face sealing layer 16 on all of the four end faces, the laminated film 10 shown in FIGS. 1A and 1B is prepared. As described above, according to the present invention, the composition 16a can be prevented from adhering to an unnecessary portion at the corners of the functional layer laminate. Therefore, it is possible to prevent the end face sealing layer 16 from being unnecessarily enlarged at the corners. Alternatively, because the end faces of the functional layer laminate are tapered, the end face sealing layer 16 can be prevented from being formed on the main surface of the laminated film.

In the example shown in FIG. 7C, a constitution is illustrated in which the end face of the functional layer laminate 18 is brought into contact with the liquid film 42, and then the functional layer laminate 18 is moved up in the vertical direction such that the liquid film 42 and the functional layer laminate 18 are separated from each other. However, the present invention is not limited thereto, and the liquid film 42 (flat plate 40) may be moved down in the vertical direction, or the functional layer laminate 18 and the liquid film 42 (flat plate 40) may be moved respectively,

In the example shown in FIG. 7B, a constitution is illustrated in which the end face of the functional layer laminate 18 is moved down in the vertical direction such that the end face comes into contact with the liquid film 42. However, the present invention is not limited thereto as long as the end face can be brought into contact with the liquid film 42 having a predetermined thickness H.

In the examples shown in FIGS. 7A to 7C, a constitution is illustrated in which the end face of a single sheet of functional layer laminate 18 is brought into contact with the liquid film 42. However, the present invention is not limited thereto, and a constitution may be adopted in which a plurality of sheets of functional layer laminates 18 are collectively brought into contact with the liquid film 42.

For example, functional layer laminates 18 and spacers may be alternately laminated such that the functional layer laminates 18 are separated from each other, and in this state, the end faces thereof may be brought into contact with the liquid film 42 of the composition forming the end face sealing layer 16 in the same manner as described above such that the end face sealing layer 16 is formed on the end faces of each of the functional layer laminates 18.

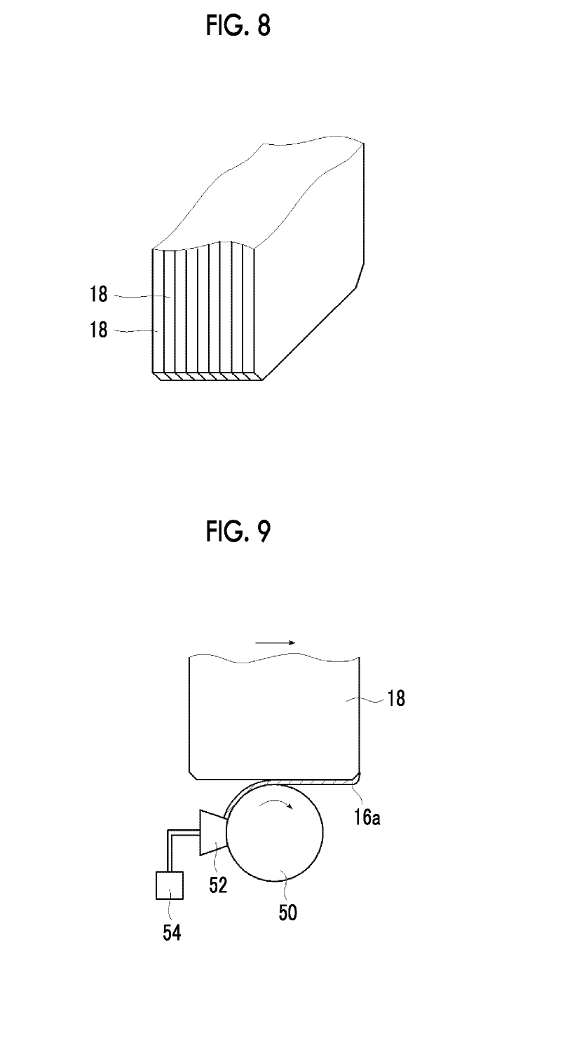

Alternatively, as shown in FIG. 8, on the entirety of the end faces of a laminated material obtained by stacking a plurality of functional layer laminates 18 (for example, 1,000 sheets), the end face sealing layer 16 is formed in the same manner as described above, and then the stacked functional layer laminates 18 may be separated by one by one, thereby preparing the laminated film 10. At this time, the end face sealing layer may be formed by stacking (binding) the functional layer laminates 18 prepared one by one or prepared by a plurality of sheets. Alternatively, the end face sealing layer may be formed by preparing a product obtained by stacking a plurality of sheets of functional layer laminates 18. This point will be also applied to other methods for forming an end face sealing layer.

In the examples shown in FIGS. 7A to 7C, a constitution is illustrated in which during the sealing layer forming step, the liquid film 42 of the composition is formed on a flat plate, and the end face of the functional layer laminate 18 is brought into contact with the liquid film 42 such that the end face of the functional layer laminate 18 is coated with the composition that becomes the end face sealing layer 16. However, the present invention is not limited thereto.

For example, a constitution shown in FIG. 9 may be adopted in which the coating film of the composition is fanned on a rotating roller, and the end face of the functional layer laminate is brought into contact with the coating film on the roller such that the end face sealing layer is formed.

The device shown in FIG. 9 has a tank 54 that stores the composition, a coating portion 52 that coats the peripheral surface of a roller 50 with the composition supplied from the tank 54, and the roller 50 that forms a coating film on the peripheral surface thereof. While the functional layer laminate 18 is being transported in a predetermined direction in synchronization with the rotating roller 50, the end face of the functional layer laminate 18 is brought into contact with the coating film on the roller 50 such that the composition 16a adheres to the end face. Then, the composition 16a is dried and, if necessary, cured by ultraviolet irradiation, heating, and the like, thereby forming the end face sealing layer 16.

Hitherto, the laminated film of the present invention has been specifically described, but the present invention is not limited to the above examples. It goes without saying that the present invention may be ameliorated or modified in various ways within a scope that does not depart from the gist of the present invention.

### EXAMPLES

Hereinafter, the present invention will be more specifically described based on specific examples of the present invention. The present invention is not limited to the examples described below, and the materials, the amount and proportion of the materials used, the treatment content, the treatment sequence, and the like shown in the following examples can be appropriately modified as long as the modification does not depart from the gist of the present invention.

### Example 1

As Example 1, the laminated film 10 shown in FIG. 1 was prepared.

<Preparation of Gas Barrier Layer 14>

<<Support 20>>

As a support of the gas barrier layer 14, a polyethylene terephthalate film (PET film, manufactured by Toyobo Co., Ltd, trade name: COSMOSHINE A4300, thickness: 50 μm, width: 1,000 mm, length: 100 m) was used.

<<Formation of Organic Layer 24>>

The organic layer 24 was formed on one surface of the support 20 as below.

First, a composition for forming the organic layer 24 was prepared. Specifically, trimethylolpropane triacrylate (TMPTA, manufactured by Daicel SciTech) and a photopolymerization initiator (manufactured by Lamberti S.p.A, ESACURE KTO46) were prepared, weighed such that a mass ratio of TMPTA:photopolymerization initiator became 95:5, and dissolved in methyl ethyl ketone, thereby preparing a composition with a concentration of solid contents of 15%.

By using the composition, the organic layer 24 was formed on one surface of the support 20 by a general film forming device which forms a film by a coating method using RtoR.

First, by using a die coater, one surface of the support 20 was coated with the composition. The support 20 having undergone coating was passed through a drying zone with a temperature of 50° C. for 3 minutes and then irradiated with ultraviolet rays (cumulative irradiation amount: about 600 mJ/cm²) such that the composition was cured, thereby forming the organic layer 24.

Furthermore, in the pass roll obtained immediately after the ultraviolet ray curing, as a protective film, a polyethylene film (PE film, manufactured by Sun A Kaken Co., Ltd., trade name: PAC 2-30-T) was bonded to the surface of the organic layer 24, and the resulting film was transported and wound up.

The thickness of the formed organic layer 24 was 1 μm.

<<Formation of Inorganic Layer 26>>

Then, by using a CVD device using RtoR, the inorganic layer 26 (silicon nitride (SiN) layer) was formed on the surface of the organic layer 24.

The support 20 on which the organic layer 24 was formed was fed from a feeding machine, and before an inorganic layer was formed, the protective film was peeled off after the laminate passed the last film surface-touching roll. Then, on the exposed organic layer 24, the inorganic layer 26 was formed by plasma CVD.

For forming the inorganic layer 26, as raw material gases, silane gas (flow rate: 160 sccm), ammonia gas (flow rate: 370 sccm), hydrogen gas (flow rate: 590 sccm), and nitrogen gas (flow rate: 240 sccm) were used. As a power source, a high-frequency power source having a frequency of 13.56 MHz was used. The film forming pressure was 40 Pa.

The thickness of the formed inorganic layer 26 was 50 nm.

The flow rate represented by the unit sccm is a value expressed in terms of a flow rate (cc/min) at 1,013 hPa and 0° C.

<<Formation of Organic Layer 28>>

Furthermore, the organic layer 28 was laminated on the surface of the inorganic layer 26 as below.

First, a composition for forming the organic layer 28 was prepared. Specifically, a urethane bond-containing acryl polymer (manufactured by TAISEI FINE CHEMICAL CO., LTD., ACRIT 8BR500, mass-average molecular weight: 250,000) and a photopolymerization initiator (IRGACURE 184 manufactured by BASF SE) were prepared, weighed such that a mass ratio of urethane bond-containing acryl polymer:photopolymerization initiator became 95:5, and dissolved in methyl ethyl ketone, thereby preparing a composition with a concentration of solid contents of 15% by mass.

By using the composition, the organic layer 28 was formed on the surface of the inorganic layer 26 by using a general film forming device that forms a film by a coating method using RtoR.

First, by using a die coater, one surface of the support 20 was coated with the composition. The support 20 having undergone coating was passed through a drying zone with a temperature of 100° C. for 3 minutes, thereby forming the organic layer 28.

In this way, the gas barrier layer 14 shown in FIG. 2 was prepared in which the organic layer 24, the inorganic layer 26, and the organic layer 28 were formed on the support 20. The thickness of the farmed organic layer 24 was 1 μm.

In the pass roll obtained immediately after drying of the composition, as a protective film, a polyethylene film was bonded to the surface of the organic layer 28 in the same manner as described above, and then the gas barrier layer 14 was wound up.

<Preparation of Functional Layer Laminate 18>

A composition having the following makeup was prepared which was for forming a quantum dot layer as the functional layer 12.

(Makeup of Composition)

| | | |
|---|---|---|
| Toluene dispersion liquid of quantum dot 1 | 10 | parts by mass |
| (emission maximum: 520 nm) | | |
| Toluene dispersion liquid of quantum dot 2 | 1 | part by mass |
| (emission maximum: 630 nm) | | |
| Lauryl methacrylate | 2.4 | parts by mass |
| Trimethylolpropane triacrylate | 0.54 | parts by mass |
| Photopolymerization initiator (IRGACURE | 0.009 | parts by mass |
| 819 (manufactured by BASF SE)) | | |

As the quantum dots 1 and 2, the following nanocrystals having a core-shell structure (InP/ZnS) were used.
Quantum dot 1: INP 530-10 (manufactured by NN-LABS, LLC)
Quantum dot 2: INP 620-10 (manufactured by NN-LABS, LLC)

The viscosity of the prepared composition was 50 mPa·s.

By using the composition and a general film forming device that forms a film by a coating method using RtoR, a functional layer laminate was prepared in which the gas barrier layer 14 was laminated on both surfaces of the functional layer 12.

Two sheets of gas barrier layers 14 were loaded on the film forming device at a predetermined position and transported. First, the protective film of one of the gas harder layers was peeled, and then the surface of the organic layer 28 was coated with the composition by using a die coater. Thereafter, the protective film was peeled from the other gas barrier layer 14, and then the gas barrier layers 14 was laminated in a state where the organic layer 28 faced the composition.

Furthermore, the laminate in which the composition that becomes the functional layer 12 was sandwiched between the gas barrier layers 14 was irradiated with ultraviolet rays (cumulative irradiation amount: about 2,000 mJ/cm²), such that the composition was cured, and that the functional layer 12 was formed. In this way, a functional layer laminate was prepared in which the gas barrier layer 14 was laminated on both surfaces of the functional layer 12. The thickness of the functional layer 12 was 46 μm.

By using a Thomson blade with a blade edge angle of 17°, the prepared laminate was cut in the form of a sheet having a planar shape in which the corners of a rectangle with A4 size are cut in the form of a straight line. In this way, the functional layer laminate 18 shown in FIGS. 1A and 1B was prepared. The length a of one side of the cut at the corner of the end face was set to be 0.5 mm (see FIG. 3C).

As a composition forming the end face sealing layer 16, a composition containing solid contents having the following makeup was prepared. Herein, the makeup is represented by part by mass that is determined in a case where the total solid content is regarded as being 100 parts by mass.

| | |
|---|---|
| Main agent of two liquid-type thermosetting epoxy | 32 parts by mass |
| resin (manufactured by MITSUBISHI GAS | |
| CHEMICAL COMPANY, INC., M-100) | |
| Curing agent of two liquid-type thermosetting epoxy | 68 parts by mass |
| resin (manufactured by MITSUBISHI GAS | |
| CHEMICAL COMPANY, INC., C-93) | |
| 1-Butanol | 60 parts by mass |

The flat plate 40 shown in FIGS. 7A to 7C was coated with the prepared composition, thereby forming the liquid film 42 having a thickness of 200 μm. Then, as shown in FIGS. 7A to 7C, the end face of the functional layer laminate 18 was brought into contact with the liquid film 42 and then lifted up in a vertical direction, such that a predetermined amount of the composition adhered to the end face. Thereafter, by drying and curing the composition for 10 minutes at 80° C., the end face sealing layer 16 was formed.

The thickness T of the formed end face sealing layer 16 was 60 μm, and the end face sealing layer 16 had a semicircular cross-sectional shape.

The end face sealing layer 16 was formed on all of the four end faces of the functional layer laminate 18 in the same manner as described above, thereby preparing the laminated film 10. The end face sealing layer 16 was formed on the entirety of each of the end faces of the functional layer laminate 18 including the cut corners.

Furthermore, on a biaxially oriented polyester film (manufactured by TORAY INDUSTRIES, INC., LUMIRROR T60), a sample for measuring oxygen permeability having a thickness of 60 μm was prepared in exactly the same manner as used for preparing the end face sealing layer 16. Then, the sample for measuring oxygen permeability was peeled from the polyester film, and by using a measurement instrument (manufactured by NIPPON API CO., LID.) adopting an APIMS method (atmospheric pressure ionization mass spectrometry), the oxygen permeability was measured under the condition of a temperature of 25° C. and a humidity of 60% RH.

As a result, the oxygen permeability of the sample for measuring oxygen permeability, that is, the end face sealing layer 16 was 0.7 cc/(m²·day·atm).

### Example 2

A laminated film was prepared in the same manner as in Example 1, except that the functional layer laminate was caused to have an arc-like planar shape in which the central angle of the cut at the corner was 90° as in the functional layer laminate 18A shown in FIG. 4.

The radius r of the arc was set to be 0.5 mm.

### Example 3

A laminated film was prepared in the same manner as in Example 1, except that the functional layer laminate was caused to have a planar shape in which the corner is cut out in the form of a square as in the functional layer laminate 18B shown in FIG. 5.

The length b of the cut at the corner of the end face was set to be 0.5 mm.

### Comparative Example 1

A laminated film was prepared in the same manner as in Example 1, except that a cut was not formed at the corners of the functional layer laminate.

[Evaluation]

The laminated films of Examples 1 to 3 and Comparative Example 1 prepared as above were evaluated in terms of the performance deterioration (barrier properties) of the edge and the corner shape of the laminated film.

<Barrier Properties>

Before and after the laminated film was being left to stand in an environment with a temperature of 60° C. and a relative humidity of 90% for 1,000 hours, the brightness of light was measured which was radiated from the backlight of a commercially available LCD, incident on the laminated film, and then emitted from the laminated film. By comparing the brightnesses with each other that were measured before and after the laminated film was being left to stand in the high-temperature and high-humidity environment, a degree of performance deterioration of the edge of the laminated film was measured, and the barrier properties of the end face sealing layer were evaluated.

As a result, in all of the laminated films, the end face sealing layer had sufficient barrier properties.

<Corner Shape>

The shape of the end face sealing layer 16 at the corner of the laminated film was evaluated in the following manner.

That is, because the laminated film had A4 size (297×210 mm), and the thickness T of the end face sealing layer 16 was 60 μm, in a case where a laminated film satisfied both the condition of “the size of the laminated film in the longitudinal direction did not exceed 297.12 mm in any position within the entire region in the transverse direction” and the condition of “the size of the laminated film in the transverse direction did not exceed 210.12 mm in any position within the entire region in the longitudinal direction”, the laminated film was evaluated to be appropriate. In a case where a laminated film did not satisfy any one of the conditions, the laminated film was evaluated to be inappropriate.

As a result, all of Examples 1 to 3 were appropriate while Comparative Example 1 was inappropriate.

### Example 4

The gas barrier layer 14 was laminated on both surfaces of the functional layer 12 in the same manner as in Example 1, thereby preparing a laminate.

Four end faces of the laminate were processed by cutting, thereby preparing the functional layer laminate 32 shown in FIG. 6A in which the end face had a tapered shape inclining to one side.

The length d of the taper was set to be 150 mm.

As described above, the thickness of the gas barrier layer 14 is 52.05 μm (50 μm+1 μm+0.05 μm+1 μm), and the thickness of the functional layer 12 is 46 μm. Accordingly, the thickness of the functional layer laminate 32 is 151 μm.

Then, the end face sealing layer 16 having a thickness of 60 μm was formed on the end faces of the functional layer laminate 32 in the same mariner as in Example 1, thereby preparing a laminated film. The amount of the functional layer laminate 32 immersed in the liquid film 42 was the same as the length d of the taper.

### Example 5

A laminated film was prepared in the same manner as in Example 4, except that the end faces of the functional layer laminate were caused to have a tapered shape having an apex positioned inside the end faces as shown in FIG. 6B.

[Evaluation]

The laminated films of Examples 4 and 5 and Comparative Example 1 prepared as above were evaluated in terms of the performance deterioration (barrier properties) of the edge and the flatness of the laminated film.

<Barrier Properties>

The barrier properties of the end face sealing layer were evaluated in the same manner as described above.

As a result, in all of the laminated films, the end face sealing layer had sufficient barrier properties.

<Flatness>

The formation of the end face sealing layer on the main surface of the laminated film was checked by visual observation.

As a result, it was confirmed that the end face sealing layer was not formed on the main surface of the laminated film in all of Examples 4 and 5, and the laminated films had excellent flatness. In contrast, it was confirmed that the end face sealing layer was formed on the main surface in the laminated film of Comparative Example 1, and the flatness of the laminated film was poor.

The above results clearly show the effects of the present invention.

### EXPLANATION OF REFERENCES

10, 30, 36: laminated film

12: (optically) functional layer

14: gas barrier layer

16: end face sealing layer

18, 18A, 18B, 32, 38, 100: functional layer laminate

20: support

24, 28: organic layer

26: inorganic layer

40: flat plate

42: liquid film

50: roller

52: coating portion

54: tank

What is claimed is:

1. A laminated film comprising:
a functional layer laminate including a functional layer and a gas barrier layer laminated on at least one main surface of the functional layer; and
an end face sealing layer covering at least some of end faces of the functional layer laminate,
wherein a planar shape of the functional layer laminate is a shape in which corners of a polygon are cut out.

2. The laminated film according to claim 1,
wherein the planar shape of the functional layer laminate is a shape in which the corners of a polygon are chamfered at least in the form of a straight line or a curved line.

3. The laminated film according to claim 2,
wherein a length of one side of the chamfered portion is 0.1 to 1 mm, or the chamfered portion is an arc having a radius of 0.1 to 1 mm.

4. The laminated film according to claim 1,
wherein the planar shape of the functional layer laminate is a shape in which the corners of a polygon are cut out in the form of a quadrangle.

5. The laminated film according to claim 4,
wherein a length of one side of the quadrangle is 0.1 to 1 mm.

6. The laminated film according to claim 1,
wherein the planar shape of the functional layer laminate is a shape in which the corners of a rectangle or a square are cut out.

7. The laminated film according to claim 1,
wherein the planar shape of the functional layer laminate is a shape in which all the corners of a polygon are cut out.

8. A laminated film comprising:
a functional layer laminate including a functional layer and a gas barrier layer laminated on at least one main surface of the functional layer; and
an end face sealing layer covering at least some of end faces of the functional layer laminate,
wherein the at east some of the end faces of the functional layer laminate have a tapered shape.

9. The laminated film according to claim 8,
wherein the end faces of the functional layer laminate have a tapered shape inclining to one side.

10. The laminated film according to claim 8,
wherein the end faces of the functional layer laminate have a tapered shape having an apex.

11. The laminated film according to claim 8,
wherein all the end faces of the functional layer laminate have a tapered shape.
